(19) United States
(12) Patent Application Publication
(10) Pub. No.: US 2019/0006021 A1
(43) Pub. Date: Jan. 3, 2019

(54) LEAKAGE DETECTION FOR INTER-BLOCK SGD-WL SHORTS IN STORAGE DEVICES

(71) Applicant: SanDisk Technologies LLC, Plano, TX (US)

(72) Inventors: Ashish Ghai, Mountain View, CA (US); Lakshmi Kalpana Vakati, Fremont, CA (US); Ekamdeep Singh, San Jose, CA (US); Gopinath Balakrishnan, Fremont, CA (US)

(73) Assignee: SanDisk Technologies LLC, Plano, TX (US)

(21) Appl. No.: 15/637,933

(22) Filed: Jun. 29, 2017

(51) Int. Cl. G11C 29/04; G11C 29/02; G11C 16/16; G11C 16/04; G11C 16/34; G11C 11/56

(52) U.S. Cl. CPC G11C 29/04; G11C 29/025; G11C 16/16; G11C 2029/1202; G11C 16/3422; G11C 11/5628; G11C 16/0483

(57) ABSTRACT

A leakage current detection circuit is configured to perform an inter-block leakage current detection process to detect for leakage current between a select gate bias line associated with a first block and one or more word lines associated with a second block. During a time period, a first switching circuit may bias the select gate bias line of the first block with a first leakage detection voltage, and a second switching circuit may bias the word lines of the second block with a second leakage detection voltage. During this time period, a current sensing circuit may sense for leakage current in a global select gate bias line.

### BACKGROUND

In a storage device, a memory array can have defects that occur during manufacturing of the storage device or during the operating life of the storage device. Defective bias lines are one type of defect that can occur in the memory array. One way a bias line can be defective is when there is a short between it and another component of the array, such as the substrate on which the memory array is located, or another bias line near or adjacent to it, such as an adjacent or neighboring bias line. Another way a bias line can be defective is when the word line is broken. In many cases, data cannot be programmed into or read from memory cells connected to a defective bias line. As such, it may be desirable for the storage device to know ahead of time if bias lines in a block are defective.

A short between a bias line and another component of the memory array may cause leakage current to flow between the bias line and the other component. Sensing for and measuring an amount of leakage current may indicate whether a bias line is defective.

Two types of bias lines in a memory array include word lines and drain select gate bias (SGD) lines. For some example layouts, including three-dimensional (3-D) layouts, a word line in one block may be close enough to a SGD line in another block such that a short may exist between the word line and the SGD line. In the event that a short exists, performing a programming operation on the word line may cause a program disturb on a drain select gate transistor connected to the SGD line by increasing the threshold voltage of the drain select gate transistor. In the array, a string of memory cells connected to the drain select gate transistor may be storing data at the time of the program disturb. If the increase in the threshold voltage V_{TH} exceeds a maximum SGD read voltage, the data stored in those memory cells may not be recoverable. Thus, ways to detect for shorts between SGD lines and word lines of different blocks may be desirable.

### BRIEF DESCRIPTION OF THE DRAWINGS

The accompanying drawings, which are incorporated in and constitute a part of this specification illustrate various aspects of the invention and together with the description, serve to explain its principles. Wherever convenient, the same reference numbers will be used throughout the drawings to refer to the same or like elements.

FIG. 1A is a block diagram of an exemplary non-volatile memory system.

FIG. 1B is a block diagram of a storage module that includes a plurality of non-volatile memory systems.

FIG. 1C is a block diagram of a hierarchical storage system.

FIG. 2A is a block diagram of exemplary components of a controller of the non-volatile memory system of FIG. 1A.

FIG. 2B is a block diagram of exemplary components of a non-volatile memory die of the non-volatile memory system of FIG. 1A.

FIG. 3 is a circuit diagram of an example floating gate transistor.

FIG. 4 is a graph of curves of drain-to-source current as a function of control gate voltage drawn through a floating gate transistor.

FIG. 5A is a block diagram of a plurality of memory cells organized into blocks.

FIG. 5B is a block diagram of a plurality of memory cells organized into blocks in different planes.

FIG. 6 is a circuit diagram of an example two-dimensional NAND-type flash memory array.

FIG. 7 is an example physical structure of a three-dimensional (3-D) NAND string.

FIG. 8 is an example physical structure of a U-shaped 3-D NAND string.

FIG. 9 is a cross-sectional view of a 3-D NAND memory array with U-shaped NAND strings in the y-z plane.

FIG. 10A is a cross-sectional view along the bit line direction (along the y-direction) of an example memory structure in which straight vertical NAND strings extend from common source connections in or near a substrate to global bit lines that extend over physical levels of memory cells.

FIG. 10B is a circuit diagram of separately-selectable sets of NAND strings of FIG. 10A.

FIG. 10C is a circuit diagram of a separately selectable set of NAND strings in cross section along the x-z plane.

FIG. 11A is a plot of threshold voltage distribution curves for memory cells storing two bits of data.

FIG. 11B is a plot of threshold voltage distribution curves for memory cells storing three bits of data.

FIG. 11C is a plot of threshold voltage distribution curves for memory cells storing four bits of data.

FIG. 12 is a partial circuit schematic diagram of control gate (CG) voltage communication circuitry that is configured to communicate a set of CG voltages from peripheral circuitry 152 of FIG. 2B to an N-number of blocks.

FIG. 13A is a top view of an example structural or physical layout of the N-number of blocks of FIG. 12.

FIG. 13B is a top view of a kth block of the N-number of blocks of FIG. 13A.

FIG. 13C is a top view of two physically adjacent transfer regions, with a short between a drain select gate bias line of one transfer region and a word line of the other transfer region.

FIG. 14 is a partial circuit schematic diagram of leakage current detection circuitry connected to a selected block and an unselected block via the CG voltage communication circuitry according to a first example leakage current detection process.

FIG. 15 is a partial circuit schematic diagram of the leakage current detection circuitry of FIG. 14 connected to two selected blocks via the CG voltage communication circuitry according to a second example leakage current detection process.

### DETAILED DESCRIPTION

Overview

By way of introduction, the below embodiments relate to systems, apparatuses, devices, circuits, and methods for inter-block leakage current detection processes between a select gate bias line and one or more word lines. In a first embodiment, a circuit includes a memory array including a plurality of memory cells arranged into a plurality of blocks, a control circuit, a first switching circuit, a second switching circuit, and a current sensing circuit. The control circuit is configured to identify a first block of the plurality of blocks and a second block of the plurality of blocks. The first switching circuit is configured to bias a select gate bias line of the first block with a first leakage detection voltage. The second switching circuit is configured to bias one or more word lines of the second block with a second leakage detection voltage. The current sensing circuit is configured to sense for leakage current between the select gate bias line of the first block and the one or more word lines of the second block during concurrent bias of the select gate bias line of the first block with the first leakage detection voltage and the one or more word lines of the second block with the second leakage detection voltage.

In some embodiments, a comparison circuit is configured to compare a level of the leakage current with a threshold current level, and output a comparison result signal indicative of the comparison to the control circuit.

In some embodiments, the current sensing circuit is configured to sense for leakage current caused by a short between the select gate bias line of the first block and the one or more word lines of the second block.

In some embodiments, the control circuit is further configured to determine to perform an inter-block leakage current detection process in response to receipt of a host write request, and identify the first block and the second block in response to the determination.

In some embodiments, the word line voltage includes a ground reference voltage, and the switching circuit is configured to connect the one or more word lines to a ground reference to bias the one or more word lines to the ground reference voltage.

In some embodiments, the control circuit is further configured to: identify the first block as a selected block, and identify a plurality of blocks in a plane besides the first block as unselected blocks, where the selected block comprises one of the unselected blocks.

In some embodiments, the plurality of blocks in the plane besides the first block comprises all of the blocks in the plane besides the first block.

In some embodiments, a logic gate circuit is configured to control the switching circuit, where the logic gate circuit is configured to activate the switching circuit to bias the one or more word lines to the second leakage detection voltage in response to receipt of an inverse block select signal associated with the second block and a leakage detection signal indicating that the control circuit wants to perform an inter-block leakage current detection process.

In some embodiments, a second switching circuit is configured to bias one or more word lines of the first block to the second leakage detection voltage, and a second logic gate is configured to control the second switching circuit, where the second logic gate circuit is configured to deactivate the second switching circuit in response to receipt of an inverse block select signal associated with the first block and the leakage detection signal indicating that the control circuit wants to perform the inter-block leakage current detection process.

In some embodiments, a third switching circuit is configured to bias a select gate bias line of the second block with the first leakage detection voltage, and a fourth switching circuit is configured to bias one or more word lines of the first block with the second leakage voltage, where the current sensing circuit is further configured to sense for leakage current further between the select gate bias line of the second block and the one or more word lines of the first block during concurrent bias of: the select gate bias line of the first block and the select gate bias line of the second block with the first leakage detection voltage, and of the one or more word lines of the first block and the one or more word lines of the second block with the second leakage detection voltage.

In some embodiments, the first block and the second block are associated with physically adjacent transfer regions.

In some embodiments, the select gate bias line includes a drain select gate bias line.

In another embodiment, a circuit includes a control circuit, a voltage supply circuit, and a leakage current detection circuit. The control circuit is configured to select two blocks of a plurality of blocks as a first selected block and a second selected block for performance of an inter-block leakage current detection process. The voltage supply circuit is configured to supply a select gate bias voltage at a first leakage detection level to a first local select gate bias line of the first selected block and to a second local select gate bias line of the second selected block, and supply a plurality of word line voltages at a second leakage detection level to one or more first local word lines associated with the first selected block and to one or more second local word lines associated with the second selected block. The leakage current detection circuit is configured to sense for leakage current between at least one of the first local select gate bias line and the one or more second local word lines, or the second local select gate bias line and the one or more first local word lines.

In some embodiments, the first selected block and the second selected block are associated with physically adjacent transfer regions.

In some embodiments, the control circuit is further configured to: in response to selection of the first selected block and the second selected block: send a first block select signal to a first set of pass transistors to select the first selected block, and send a second block select signal to a second set of pass transistors to select the second selected block.

In some embodiments, the first select gate bias line comprises a first drain select gate bias line and the second select gate bias line comprises a second drain select gate bias line.

In another embodiment, a system includes: a memory die including nonvolatile memory cells organized into a plurality of blocks, a control circuit, a voltage supply circuit, and a leakage current monitor circuit. The control circuit is configured to output a block select signal to connect local control gate lines of a selected block of the plurality of blocks with global control gate lines, where one of the local control gate lines includes a local drain select gate bias line, and output a leakage detection signal to connect local word lines of a second block to a ground reference. The voltage supply circuit is configured to supply a drain select gate bias voltage at a leakage test level to the local drain select gate bias line of the first block in response to the local control gate lines of the first block connected to the global control gate lines and the local word lines of the second block connected to the ground reference. The leakage current monitor circuit is configured to connect to the local drain select bias line of the first block in response to the output of the block select signal, and monitor for leakage current between the local drain select gate bias line of the first block and the local word lines of the second block during supply of the of the drain select gate bias voltage at the leakage test level and connection of the local word lines of the second block to the ground reference.

In some embodiments, a grounding transistor is configured to connect the local word lines of the second block to the ground reference.

In some embodiments, a logic gate circuit is configured to control the grounding transistor, and the logic gate circuit is configured to turn on the grounding transistor to bias the local word lines of the second block to a ground reference voltage associated with the ground reference in response to receipt of the leakage detection signal.

In some embodiments, the plurality of blocks are configured in a same plane.

Other embodiments are possible, and each of the embodiments can be used alone or together in combination. Accordingly, various embodiments will now be described with reference to the attached drawings.

### Embodiments

The following embodiments describe apparatuses, devices, systems, and methods for performing inter-block leakage current detection processes. Before turning to these and other embodiments, the following paragraphs provide a discussion of exemplary memory systems and storage devices that can be used with these embodiments. Of course, these are just examples, and other suitable types of memory systems and/or storage devices can be used.

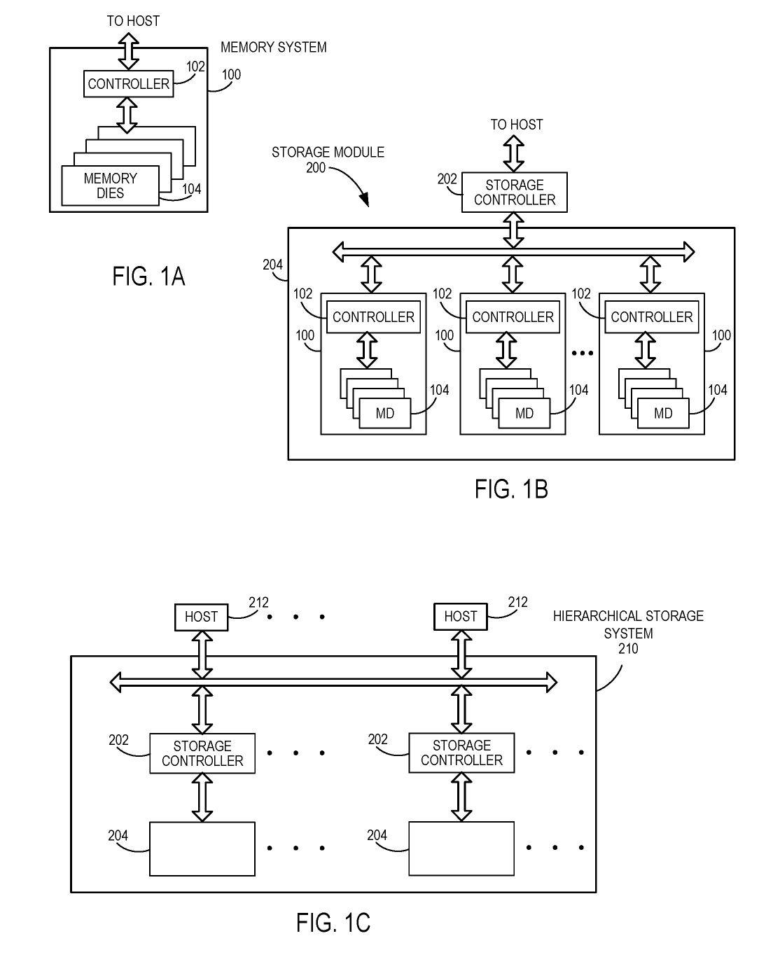

FIG. 1A is a block diagram illustrating a memory system 100. The memory system 100 may include a controller 102 and memory that may be made up of one or more memory dies 104. As used herein, the term die refers to the set of memory cells, and associated circuitry for managing the physical operation of those memory cells, that are formed on a single semiconductor substrate. The controller 102 may interface with a host system and transmit command sequences for read, program, and erase operations to the non-memory die(s) 104.

The controller 102 (which may be a flash memory controller) can take the form of processing circuitry, a microprocessor or processor, and a computer-readable medium that stores computer-readable program code (e.g., software or firmware) executable by the (micro)processor, logic gates, switches, an application specific integrated circuit (ASIC), a programmable logic controller, and an embedded microcontroller, for example. The controller 102 can be configured with hardware and/or firmware to perform the various functions described below and shown in the flow diagrams. Also, some of the components shown as being internal to the controller can also be stored external to the controller, and other components can be used. Additionally, the phrase “operatively in communication with” could mean directly in communication with or indirectly (wired or wireless) in communication with through one or more components, which may or may not be shown or described herein.

As used herein, the controller 102 is a device that manages data stored in the memory die(s) and communicates with a host, such as a computer or electronic device. The controller 102 can have various functionality in addition to the specific functionality described herein. For example, the controller 102 can format the memory dies 104 to ensure the it is operating properly, map out bad flash memory cells, and allocate spare cells to be substituted for future failed cells. Some part of the spare cells can be used to hold firmware to operate the controller 102 and implement other features. In operation, when a host needs to read data from or write data to the memory die(s) 104, the host will communicate with the controller 102. If the host provides a logical address to which data is to be read/written, the controller 102 can convert the logical address received from the host to a physical address in the memory die(s) 104. (Alternatively, the host can provide the physical address). The controller 102 can also perform various memory management functions, such as, but not limited to, wear leveling (distributing writes to avoid wearing out specific blocks of memory that would otherwise be repeatedly written to) and garbage collection (after a block is full, moving only the valid pages of data to a new block, so the full block can be erased and reused).

The interface between the controller 102 and the non-volatile memory die(s) 104 may be any suitable interface, such as flash interface, including those configured for Toggle Mode 200, 400, 800, 1000 or higher. For some example embodiments, the memory system 100 may be a card based system, such as a secure digital (SD) or a micro secure digital (micro-SD) card. In alternate example embodiments, the memory system 100 may be part of an embedded memory system.

In the example illustrated in FIG. 1A, the memory system 100 is shown as including a single channel between the controller 102 and the non-volatile memory die(s) 104. However, the subject matter described herein is not limited to memory systems having a single memory channel. For example, in some memory systems, such as those embodying NAND architectures, 2, 4, 8 or more channels may exist between the controller 102 and the memory die(s) 104, depending on controller capabilities. In any of the embodiments described herein, more than a single channel may exist between the controller and the memory die(s)s 104, even if a single channel is shown in the drawings.

FIG. 1B illustrates a storage module 200 that includes plural non-volatile memory systems 100. As such, the storage module 200 may include a storage controller 202 that interfaces with a host and with a storage system 204, which includes a plurality of non-volatile memory systems 100. The interface between the storage controller 202 and non-volatile memory systems 100 may be a bus interface, such as a serial advanced technology attachment (SATA), a peripheral component interface express (PCIe) interface, an embedded MultiMediaCard (eMMC) interface, a SD interface, or a Universal Serial Bus (USB) interface, as examples. The storage module 200, in one embodiment, may be a solid state drive (SSD), such as found in portable computing devices, such as laptop computers and tablet computers, and mobile phones.

FIG. 1C is a block diagram illustrating a hierarchical storage system 210. The hierarchical storage system 210 may include a plurality of storage controllers 202, each of which control a respective storage system 204. Host systems 212 may access memories within the hierarchical storage system 210 via a bus interface. Example bus interfaces may include a non-volatile memory express (NVMe), a fiber channel over Ethernet (FCoE) interface, an SD interface, a USB interface, a SATA interface, a PCIe interface, or an eMMC interface as examples. In one embodiment, the storage system 210 illustrated in FIG. 1C may be a rack mountable mass storage system that is accessible by multiple host computers, such as would be found in a data center or other location where mass storage is needed.

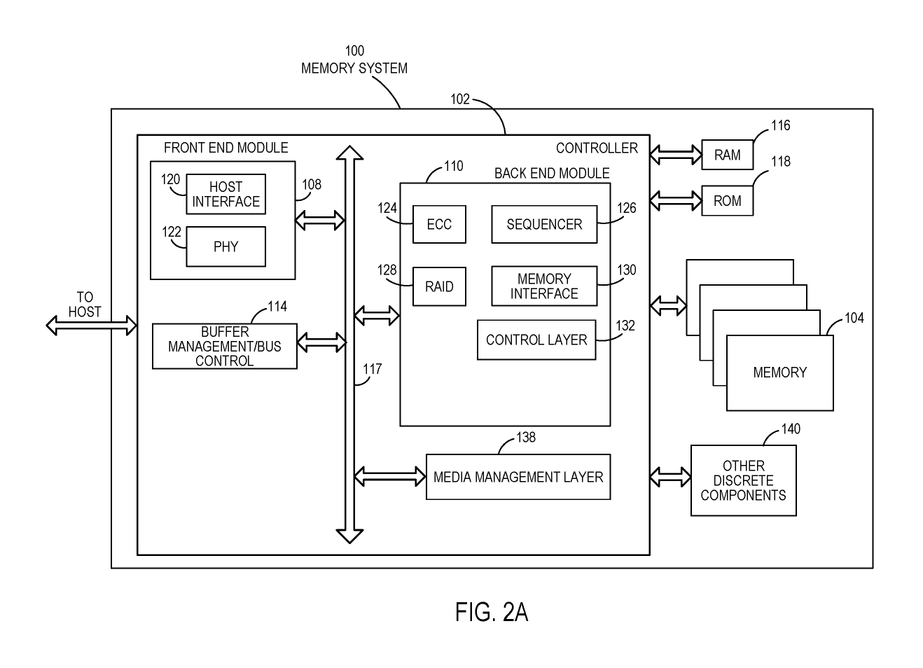

FIG. 2A is a block diagram illustrating exemplary components of the controller 102 in more detail. The controller 102 may include a front end module 108 that interfaces with a host, a back end module 110 that interfaces with the non-volatile memory die(s) 104, and various other modules that perform various functions of the non-volatile memory system 100. In general, a module may be hardware or a combination of hardware and software. For example, each module may include an application specific integrated circuit (ASIC), a field programmable gate array (FPGA), a circuit, a digital logic circuit, an analog circuit, a combination of discrete circuits, gates, or any other type of hardware or combination thereof. In addition or alternatively, each module may include memory hardware that comprises instructions executable with a processor or processor circuitry to implement one or more of the features of the module. When any one of the module includes the portion of the memory that comprises instructions executable with the processor, the module may or may not include the processor. In some examples, each module may just be the portion of the memory that comprises instructions executable with the processor to implement the features of the corresponding module without the module including any other hardware. Because each module includes at least some hardware even when the included hardware comprises software, each module may be interchangeably referred to as a hardware module.

The controller 102 may include a buffer manager/bus controller module 114 that manages buffers in random access memory (RAM) 116 and controls the internal bus arbitration for communication on an internal communications bus 117 of the controller 102. A read only memory (ROM) 118 may store and/or access system boot code. Although illustrated in FIG. 2A as located separately from the controller 102, in other embodiments one or both of the RAM 116 and the ROM 118 may be located within the controller 102. In yet other embodiments, portions of RAM 116 and ROM 118 may be located both within the controller 102 and outside the controller 102. Further, in some implementations, the controller 102, the RAM 116, and the ROM 118 may be located on separate semiconductor dies.

Additionally, the front end module 108 may include a host interface 120 and a physical layer interface (PHY) 122 that provide the electrical interface with the host or next level storage controller. The choice of the type of the host interface 120 can depend on the type of memory being used. Example types of the host interface 120 may include, but are not limited to, SATA, SATA Express, SAS, Fibre Channel, USB, PCIe, and NVMe. The host interface 120 may typically facilitate transfer for data, control signals, and timing signals.

The back end module 110 may include an error correction code (ECC) engine or module 124 that encodes the data bytes received from the host, and decodes and error corrects the data bytes read from the non-volatile memory die(s) 104. The back end module 110 may also include a command sequencer 126 that generates command sequences, such as program, read, and erase command sequences, to be transmitted to the non-volatile memory die(s) 104. Additionally, the back end module 110 may include a RAID (Redundant Array of Independent Drives) module 128 that manages generation of RAID parity and recovery of failed data. The RAID parity may be used as an additional level of integrity protection for the data being written into the non-volatile memory system 100. In some cases, the RAID module 128 may be a part of the ECC engine 124. A memory interface 130 provides the command sequences to the non-volatile memory die(s) 104 and receives status information from the non-volatile memory die(s) 104. Along with the command sequences and status information, data to be programmed into and read from the non-volatile memory die(s) 104 may be communicated through the memory interface 130. In one embodiment, the memory interface 130 may be a double data rate (DDR) interface and/or a Toggle Mode 200, 400, 800, or higher interface. A control layer 132 may control the overall operation of back end module 110.

Additional modules of the non-volatile memory system 100 illustrated in FIG. 2A may include a media management layer 138, which performs wear leveling of memory cells of the non-volatile memory die 104, address management, and facilitates folding operations as described in further detail below. The non-volatile memory system 100 may also include other discrete components 140, such as external electrical interfaces, external RAM, resistors, capacitors, or other components that may interface with controller 102. In alternative embodiments, one or more of the RAID module 128, media management layer 138 and buffer management/bus controller 114 are optional components that may not be necessary in the controller 102.

FIG. 2B is a block diagram illustrating exemplary components of a memory die 104 in more detail. The memory die 104 may include a memory cell structure 142 that includes a plurality of memory cells or memory elements. Any suitable type of memory can be used for the memory cells 142. As examples, the memory can be dynamic random access memory (“DRAM”) or static random access memory (“SRAM”), non-volatile memory, such as resistive random access memory (“ReRAM”), electrically erasable programmable read only memory (“EEPROM”), flash memory (which can also be considered a subset of EEPROM), ferroelectric random access memory (“FRAM”), and magnetoresistive random access memory (“MRAM”), and other semiconductor elements capable of storing information. Each type of memory may have different configurations. For example, flash memory devices may be configured in a NAND or a NOR configuration.

The memory can be formed from passive and/or active elements, in any combinations. By way of non-limiting example, passive semiconductor memory elements include ReRAM device elements, which in some embodiments include a resistivity switching storage element, such as an anti-fuse, phase change material, etc., and optionally a steering element, such as a diode, etc. Further by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND memory array may be configured so that the array is composed of multiple strings of memory in which a string is composed of multiple memory elements sharing a single bit line and accessed as a group. Alternatively, memory elements may be configured so that each element is individually accessible, e.g., a NOR memory array.

NAND and NOR memory configurations are exemplary, and memory elements may be otherwise configured.

The semiconductor memory elements located within and/or over a substrate may be arranged in two or three dimensions, such as a two dimensional memory structure or a three dimensional memory structure.

In a two dimensional memory structure, the semiconductor memory elements are arranged in a single plane or a single memory device level. Typically, in a two dimensional memory structure, memory elements are arranged in a plane (e.g., in an x-z direction plane) which extends substantially parallel to a major surface of a substrate that supports the memory elements. The substrate may be a wafer over or in which the layer of the memory elements are formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A three dimensional memory array is arranged so that memory elements occupy multiple planes or multiple memory device levels, thereby forming a structure in three dimensions (i.e., in the x, y and z directions, where the y direction is substantially perpendicular and the x and z directions are substantially parallel to the major surface of the substrate).

As a non-limiting example, a three dimensional memory structure may be vertically arranged as a stack of multiple two dimensional memory device levels. As another non-limiting example, a three dimensional memory array may be arranged as multiple vertical columns (e.g., columns extending substantially perpendicular to the major surface of the substrate, i.e., in the y direction) with each column having multiple memory elements in each column. The columns may be arranged in a two dimensional configuration, e.g., in an x-z plane, resulting in a three dimensional arrangement of memory elements with elements on multiple vertically stacked memory planes. Other configurations of memory elements in three dimensions can also constitute a three dimensional memory array.

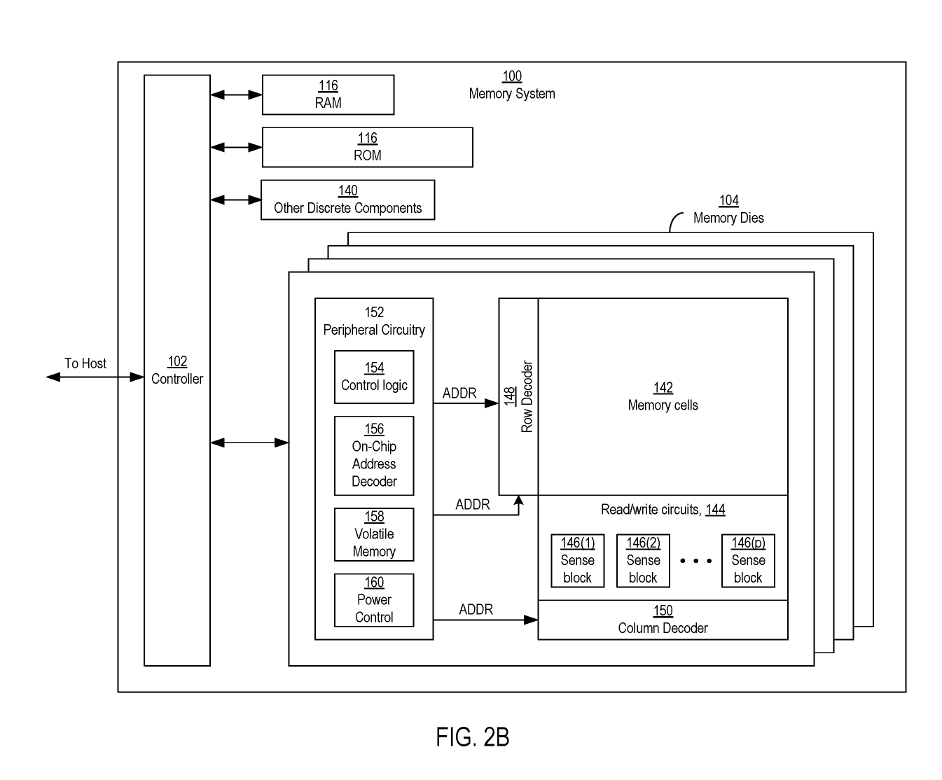

For some memory configurations, such as flash memory, a memory cell of the plurality of memory cells 142 may be a floating gate transistor (FGT). FIG. 3 shows a circuit schematic diagram of an example FGT 300. The FGT 300 may include a source 302, a drain 304, a control gate 306, a floating gate 308, and a substrate 310. The floating gate 308 may be surrounded by an insulator or insulating material that helps retain charge in the floating gate 308. The presence or absence of charges inside the floating gate 308 may cause a shift in a threshold voltage of the FGT, which is used to distinguish logic levels. For each given charge stored in the floating gate 308, a corresponding drain-to-source conduction current ID with respect to a fixed control gate Voltage V_{CG} applied to the control gate 306 occurs. Additionally, the FGT 300 may have an associated range charges that can be programmable onto its floating gate 308 that define a corresponding threshold voltage window or a corresponding conduction current window. In this way, the FGT's threshold voltage may be indicative of the data stored in the memory cell.

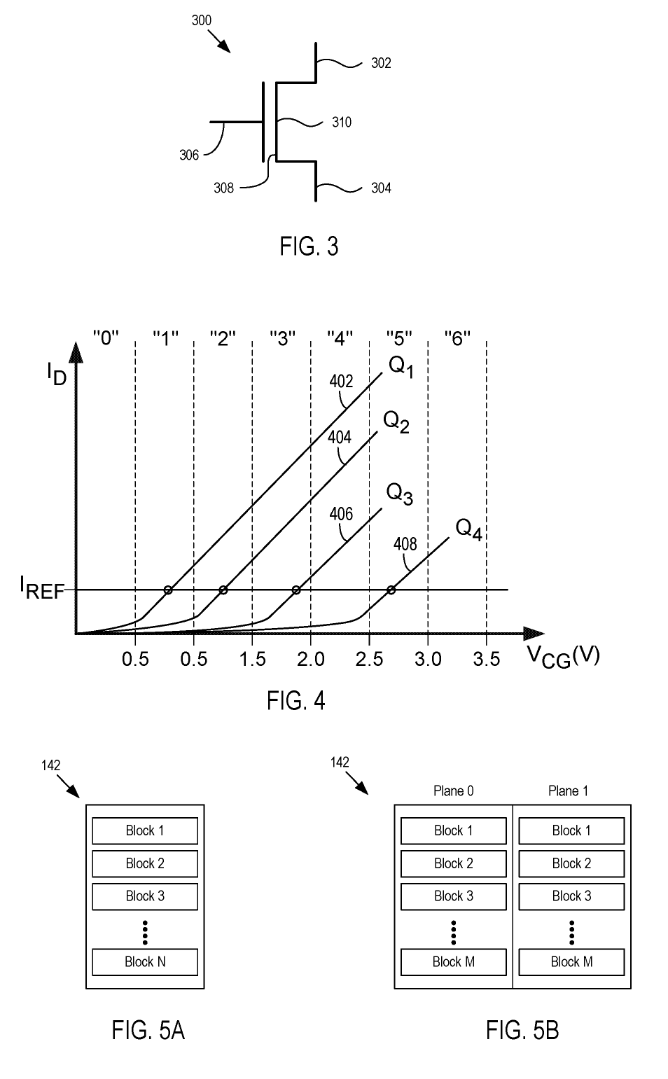

FIG. 4 is graph showing four curves 402, 404, 406, 408 of drain-to-source current ID drawn through the FGT 300 as a function of a control gate voltage V_{CG} applied to the control gate 306. Each curve 402-408 corresponds to a respective one of four different charges or charge levels Q1, Q2, Q3, Q4 that the floating gate 308 can selectively store at any given time. Otherwise stated, the four curves 402-408 represent four possible charge levels that can be programmed on the floating gate 308 of the FGT 300, respectively corresponding to four possible memory states. In the example graph in FIG. 4, the threshold voltage window of a population of FGTs range from 0.5 volts (V) to 3.5 V. Seven possible memory states “0”, “1”, “2”, “3”, “4”, “5”, and “6” are defined or extend across the threshold voltage window, and respectively represent one erased states and six programmed states. The different states can be demarcated by partitioning the threshold voltage window into six regions of 0.5 V intervals. The FGT 300 may be in one of the states according to the charge stored in its floating gate 308 and where its drain-to-source current ID intersects a reference current IREF. For example, a FGT programmed to store charge Q1 in memory state “1” since its curve 402 intersects the reference current IREF in a region of the threshold voltage region demarcated by the control gate voltage V_{CG} in a range from 0.5 V to 1.0 V. The more memory states the FGT 300 is programmed to store, the more finely divided are the regions defining the threshold voltage window. In some examples configurations, the threshold voltage window may extend from −1.5 V to 5 V, providing a maximum width of 6.5 V. If the FGT 300 can be programmed into any one of sixteen possible states, each state may occupy a respective region spanning 200 millivolts (mV) to 300 mV. The higher the resolution of the threshold voltage window (i.e., more states into which the FGT 300 can be programmed), the higher the precision that is needed in programming and reading operations to successfully read and write data. Further description of memory states and threshold voltages is provided in further detail below with respect to programming, program verify, and read operations.

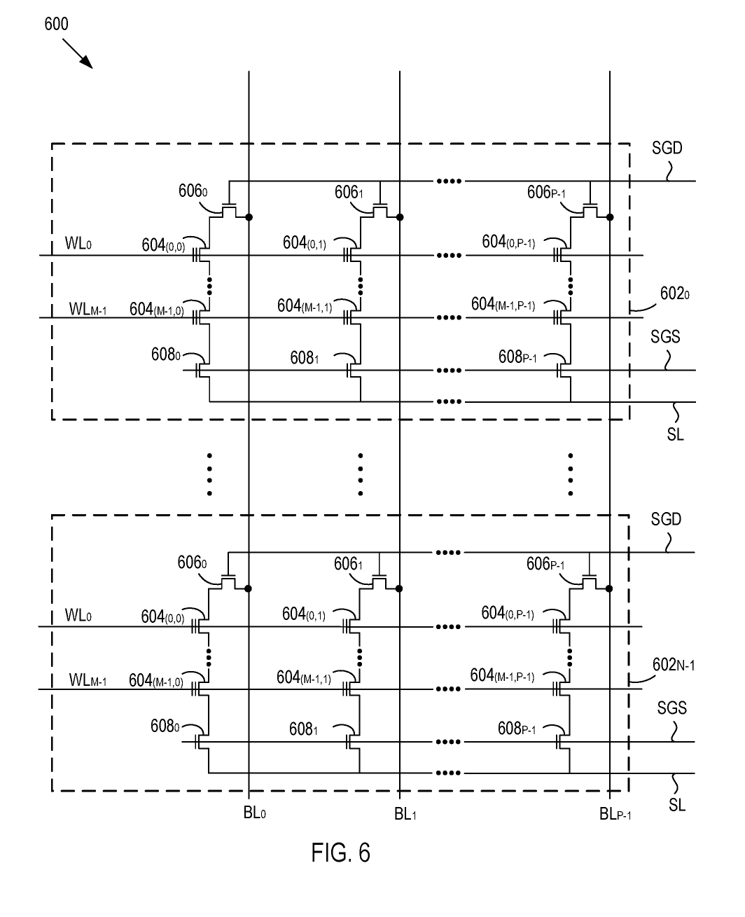

Referring to FIG. 5A, the memory cells 142 may be organized into an N-number of blocks, extending from a first block Block 1 to an Nth block Block N. Referring to FIG. 5B, for some example configurations, the N-number of blocks are organized into a plurality of planes. FIG. 5B shows an example configuration where the blocks are organized into two planes, including a first plane Plane 0 and a second plane Plane 1. Each plane is shown as included an M-number of blocks, extending from a first block Block 1 to an Mth block Block M. A plane of a memory die may be a unit of the memory die that is able to report its own operating status and can perform command execution independent of other planes. This way, two planes can perform command execution in parallel. For example, each plane may have its own data registers, data buffers, etc., to enable independent and/or parallel command operation. As one example, the controller 102 can send a multi-plane read command to the dies 104, and the dies 104 can execute the read commands in two or more planes in parallel. For example, data stored in different planes may be sensed simultaneously or independently.

For configurations where the memory cells are organized into a two-dimensional array, the memory cells may be configured in a matrix-like structure of rows and columns in each of the blocks. At the intersection of a row and a column is a memory cell. A column of memory cells is a referred to as a string, and memory cells in a string are electrically connected in series. A row of memory cells is referred to as a page. Where the memory cells are FGTs, control gates of FGTs in a page or row may be electrically connected together.

Additionally, each of the blocks includes word lines and bit lines connected to the memory cells. Each page of memory cells is coupled to a word line. Where the memory cells are FGTs, each word line may be coupled to the control gates of the FGTs in a page. In addition, each string of memory cells is coupled to a bit line. Further, a single string may span across multiple word lines, and the number of memory cells in a string may be equal to the number of pages in a block.

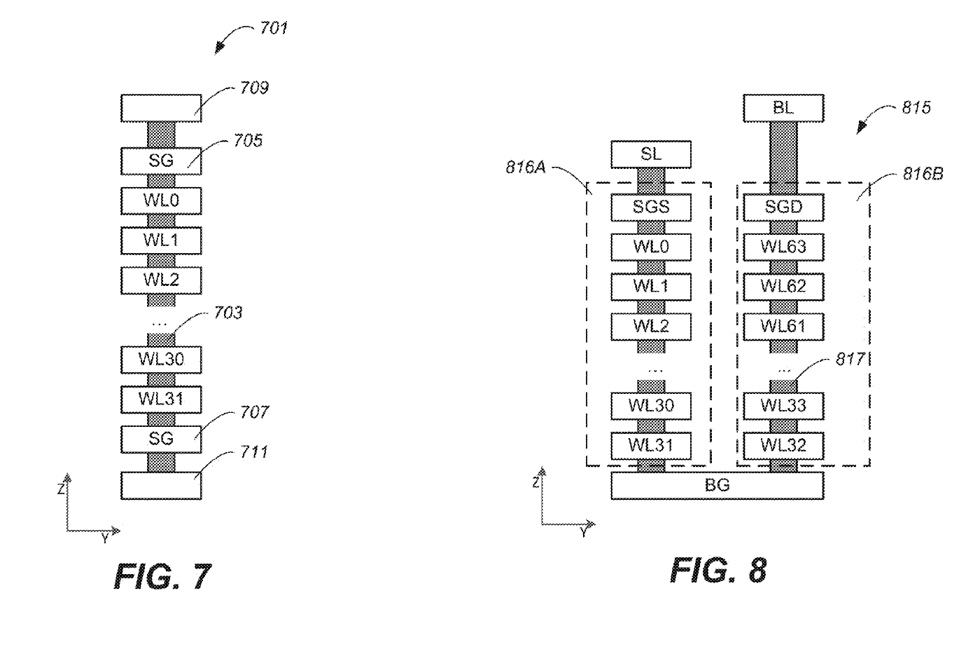

FIG. 6 is a circuit schematic diagram of at least a portion of an exemplary two-dimensional NAND-type flash memory array 600, which may be representative of at least a portion of the plurality of memory cells 142. For example, the memory array 600 may be representative of a single plane of blocks on a memory die 104. The memory array 600 may include an N-number of blocks 602₀ to 602_{N-1}. Each block 602 includes a P-number of strings of FGTs 604, with each string coupled to respective one of a P-number of bit lines BL₀ to BL_{P-1}. Additionally, each block 602 includes an M-number of pages of FGTs 604, with each page coupled to a respective one of an M-number of word lines WL₀ to WL_{M-1}. Each ith, jth FGT(i,j) of a given block 602 is connected to an ith word line WLᵢ and to a jth bit line BLⱼ of the given block. As shown in FIG. 6, bit lines BL₀ to BL_{P-1} are shared among the blocks 602₀ to 602_{N-1} may be which are shared among the blocks, such as blocks within the same plane.

Within each block 602, each string is connected at one end to an associated drain select gate transistor 606, and each string is coupled to its associated bit line BL via the associated drain select gate transistor 606. Switching of the drain select gate transistors 606₀ to 606_{P-1} may be controlled using a drain select gate bias line SGD that supplies a drain select gate bias voltage V_{SGD} to turn on and off the drain select transistors 606₀ to 606_{P-1}. In addition, within each block 602, each string is connected at its other end to an associated source select gate transistor 608, and each string is coupled to a common source line SL via the associated source select gate transistor 608. Switching of the source select gate transistors 608₀ to 608_{P-1} may be controlled using a source select gate bias line SGS that supplies a source select gate bias voltage V_{SGS} to turn on and off the source select transistors 608₀ to 608_{P-1}. Also, although not shown, in some cases, dummy word lines, which contain no user data, can also be used in the memory array 600 adjacent to the source select gate transistors 608₀ to 608_{P-1}. The dummy word lines may be used to shield edge word lines and FGTs from certain edge effects.

An alternative arrangement to a conventional two-dimensional (2-D) NAND array is a three-dimensional (3-D) array. In contrast to 2-D NAND arrays, which are formed along a planar surface of a semiconductor wafer, 3-D arrays extend up from the wafer surface and generally include stacks, or columns, of memory cells extending upwards. Various 3-D arrangements are possible. In one arrangement a NAND string is formed vertically with one end (e.g. source) at the wafer surface and the other end (e.g. drain) on top. In another arrangement a NAND string is formed in a U-shape so that both ends of the NAND string are accessible on top, thus facilitating connections between such strings.

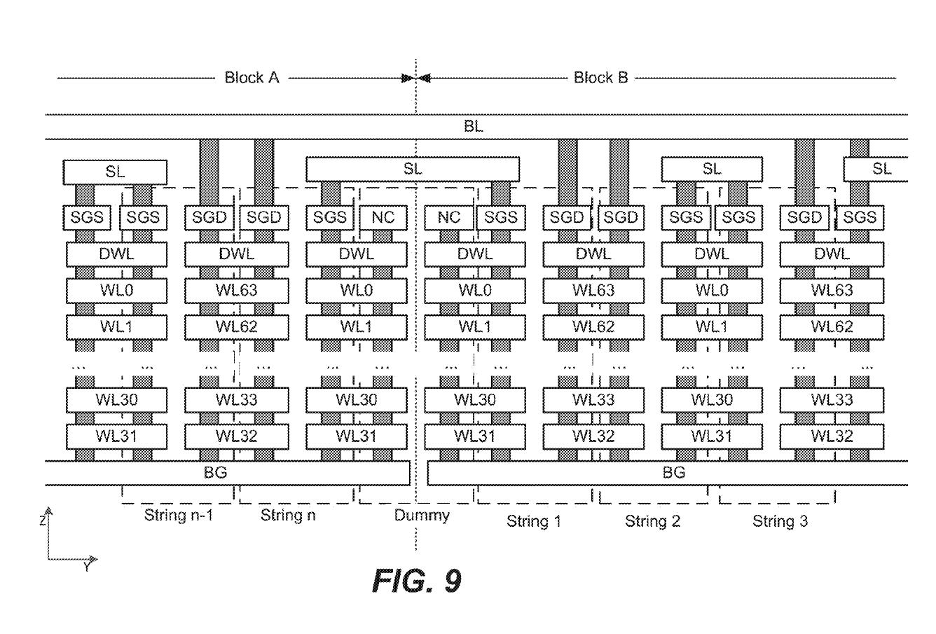

FIG. 7 shows a first example of a NAND string 701 that extends in a vertical direction, i.e. extending in the z-direction, perpendicular to the x-y plane of the substrate. Memory cells are formed where a vertical bit line (local bit line) 703 passes through a word line (e.g. WL0, WL1, etc.). A charge trapping layer between the local bit line and the word line stores charge, which affects the threshold voltage of the transistor formed by the word line (gate) coupled to the vertical bit line (channel) that it encircles. Such memory cells may be formed by forming stacks of word lines and then etching memory holes where memory cells are to be formed. Memory holes are then lined with a charge trapping layer and filled with a suitable local bit line/channel material (with suitable dielectric layers for isolation).

As with two-dimensional (planar) NAND strings, select gates 705, 707, are located at either end of the string to allow the NAND string to be selectively connected to, or isolated from, external elements 709, 711. Such external elements are generally conductive lines such as common source lines or bit lines that serve large numbers of NAND strings. Vertical NAND strings may be operated in a similar manner to planar NAND strings and both Single Level Cell (SLC) and Multi Level Cell (MLC) operation is possible. While FIG. 7 shows an example of a NAND string that has 32 cells (0-31) connected in series, the number of cells in a NAND string may be any suitable number. Not all cells are shown for clarity. It will be understood that additional cells are formed where word lines 3-29 (not shown) intersect the local vertical bit line.

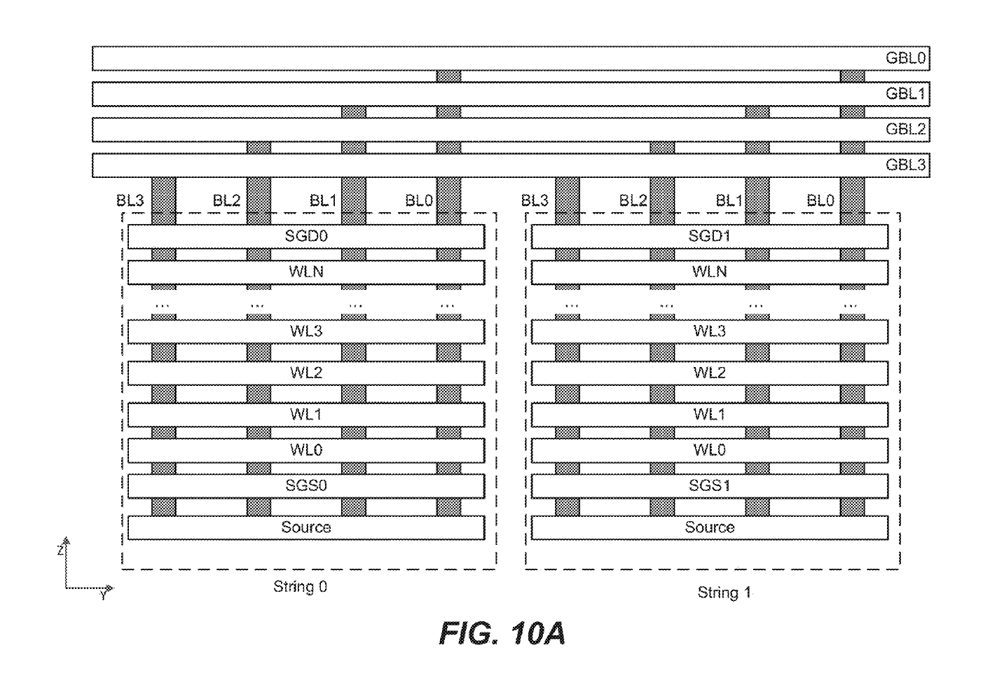

FIG. 8 shows a second example of a NAND string 815 that extends in a vertical direction (z-direction). In this case, NAND string 815 forms a U-shape, connecting with external elements (source line “SL” and bit line “BL”) located on the top of the structure. At the bottom of NAND string 815 is a controllable gate (back gate “BG”) which connects the two wings 816A, 816B of NAND string 815. A total of 64 cells are formed where word lines WL0-WL63 intersect the vertical local bit line 817 (though in other examples other numbers of cells may be provided). Select gates SGS, SGD, are located at either end of NAND string 815 to control connection/isolation of NAND string 815.

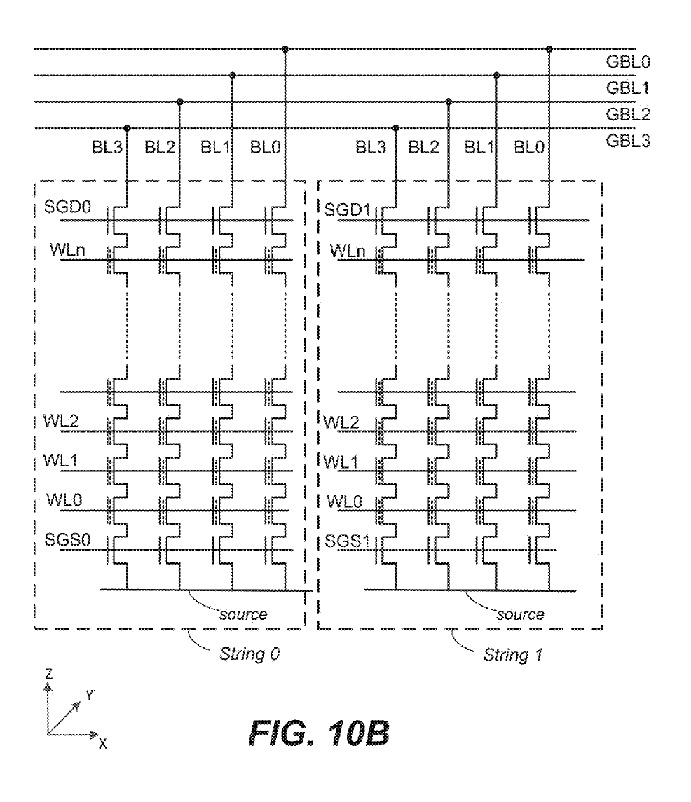

Vertical NAND strings may be arranged to form a 3-D NAND array in various ways. FIG. 9 shows an example where multiple U-shaped NAND strings in a block are connected to a bit line. In this case, there are n separately-selectable sets of strings (String 1-String n) in a block connected to a bit line (“BL”). The value of “n” may be any suitable number, for example, 8, 12, 16, 32, or more. Strings alternate in orientation with odd numbered strings having their source connection on the left, and even numbered strings having their source on the right. This arrangement is convenient but is not essential and other patterns are also possible.

Common source lines “SL” connect to one end of each NAND string (opposite to the end that connects to the bit line). This may be considered the source end of the NAND string, with the bit line end being considered as the drain end of the NAND string. Common source lines may be connected so that all source lines for a block may be controlled together by a peripheral circuit. Thus, NAND strings of a block extend in parallel between bit lines on one end, and common source lines on the other end.

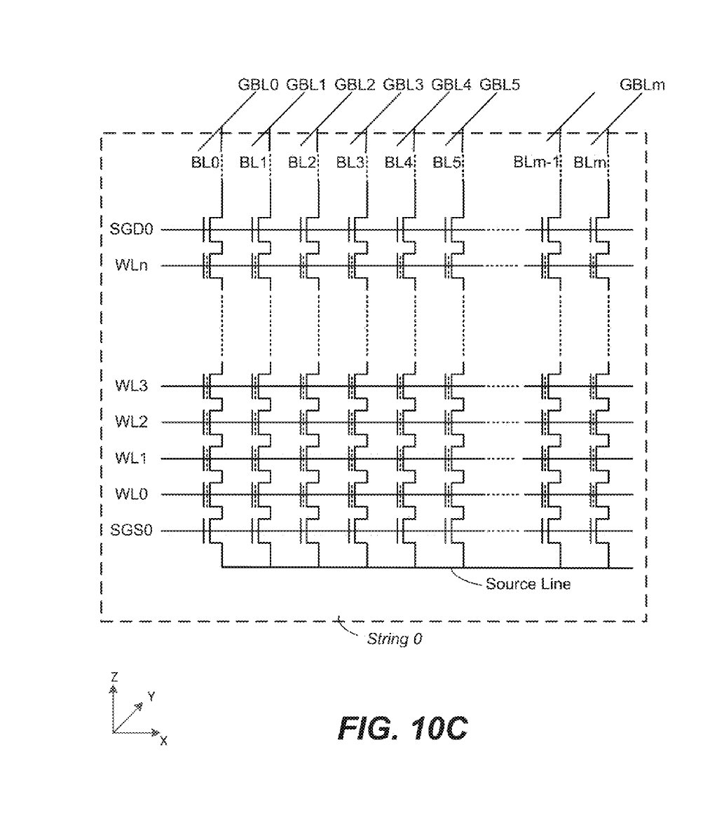

FIG. 10A shows a memory structure, in cross section along the bit line direction (along y-direction) in which straight vertical NAND strings extend from common source connections in or near a substrate to global bit lines (GBL0-GBL3) that extend over the physical levels of memory cells. Word lines in a given physical level in a block are formed from a sheet of conductive material. Memory hole structures extend down through these sheets of conductive material to form memory cells that are connected in series vertically (along the z-direction) by vertical bit lines (BL0-BL3) to form vertical NAND strings. Within a given block there are multiple NAND strings connected to a given global bit line (e.g. GBL0 connects with multiple BL0s). NAND strings are grouped into sets of strings that share common select lines. Thus, for example, NAND strings that are selected by source select line SGS0 and drain select line SGD0 may be considered as a set of NAND strings and may be designated as String 0, while NAND strings that are selected by source select line SGS1 and drain select line SGD1 may be considered as another set of NAND strings and may be designated as String 1 as shown. A block may consist of any suitable number of such separately-selectable sets of strings. It will be understood that FIG. 10A shows only portions of GBL0 GBL3, and that these bit lines extend further in the y-direction and may connect with additional NAND strings in the block and in other blocks. Furthermore, additional bit lines extend parallel to GBL0 GBL3 (e.g. at different locations along x-axis, in front of, or behind the location of the cross-section of FIG. 10A).

FIG. 10B illustrates separately-selectable sets of NAND strings of FIG. 10A schematically. It can be seen that each of the global bit lines (GBL0-GBL3) is connected to multiple separately selectable sets of NAND strings (e.g. GBL0 connects to vertical bit line BL0 of String 0 and also connects to vertical bit line BL0 of String 1) in the portion of the block shown. In some cases, word lines of all strings of a block are electrically connected, e.g. WL0 in string 0 may be connected to WL0 of String 1, String 2, etc. Such word lines may be formed as a continuous sheet of conductive material that extends through all sets of strings of the block. Source lines may also be common for all strings of a block. For example, a portion of a substrate may be doped to form a continuous conductor underlying a block. Source and drain select lines are not shared by different sets of strings so that, for example, SGD0 and SGS0 can be biased to select String 0 without similarly biasing SGD1 and SGS1. Thus, String 0 may be individually selected (connected to global bit lines and a common source) while String 1 (and other sets of strings) remain isolated from global bit lines and the common source. Accessing memory cells in a block during programming and reading operations generally includes applying select voltages to a pair of select lines (e.g. SGS0 and SGD0) while supplying unselect voltages to all other select lines of the block (e.g. SGS1 and SGD1). Then, appropriate voltages are applied to word lines of the block so that a particular word line in the selected set of strings may be accessed (e.g. a read voltage is applied to the particular word line, while read-pass voltages are applied to other word lines). Erasing operations may be applied on an entire block (all sets of strings in a block) rather than on a particular set of strings in a block.

FIG. 10C shows a separately selectable set of NAND strings, String 0, of FIGS. 10A-B in cross section along the X-Z plane. It can be seen that each global bit line (GBL0-GBLm) is connected to one vertical NAND string (vertical bit line BL0-BLm) in String 0. String 0 may be selected by applying appropriate voltages to select lines SGD0 and SGS0. Other sets of strings are similarly connected to global bit lines (GBL0-GBLm) at different locations along the Y direction and with different select lines that may receive unselect voltages when String 0 is selected.

Referring back to FIG. 2B, the memory die 104 may further include read/write circuits 144 that includes a plurality or p-number of sense blocks (also referred to as sense modules or sense circuits) 146. As described in further detail below, the sense blocks 146 are configured to participate in reading or programming a page of memory cells in parallel.

The memory die 104 may also include a row address decoder 148 and a column address decoder 150. The row address decoder 148 may decode a row address and select a particular word line in the memory array 142 when reading or writing data to/from the memory cells 142. The column address decoder 150 may decode a column address to select a particular group of bitlines in the memory array 142 to read/write circuits 144.

In addition, the non-volatile memory die 104 may include peripheral circuitry 152. The peripheral circuitry 152 may include control logic circuitry (or simply control circuit) 154, which may be implemented as a state machine, that provides on-chip control of memory operations as well as status information to the controller 102. The peripheral circuitry 152 may also include an on-chip address decoder 156 that provides an address interface between addressing used by the controller 102 and/or a host and the hardware addressing used by the row and column decoders 148, 150. In addition, the peripheral circuitry 152 may also include volatile memory 158. An example configuration of the volatile memory 158 may include latches, although other configurations are possible.

In addition, the peripheral circuitry 152 may include power control circuitry 160 that is configured to generate and supply voltages to the memory array 142, including voltages (including program voltage pulses) to the wordlines, erase voltages (including erase voltage pulses), the source select gate bias voltage V_{SSG} to the source select gate bias line SSG, the drain select gate bias voltage V_{DSG} to the drain select gate bias line DSG, a cell source voltage V_{celsrc} on the source lines SL, as well as other voltages that may be supplied to the memory array 142, the read/write circuits 144, including the sense blocks 146, and/or other circuit components on the memory die 104. The various voltages that are supplied by the power control circuitry 160 are described in further detail below. The power control circuitry 160 may include any of various circuit topologies or configurations to supply the voltages at appropriate levels to perform the read, write, and erase operations, such as driver circuits, charge pumps, reference voltage generators, and pulse generation circuits, or a combination thereof. Other types of circuits to generate the voltages may be possible. In addition, the power control circuitry 160 may communicate with and/or be controlled by the control logic circuitry 154, the read/write circuits 144, and/or the sense blocks 146 in order to supply the voltages at appropriate levels and appropriate times to carry out the memory operations.

In order to program a target memory cell, and in particular a FGT, the power control circuitry 160 applies a program voltage to the control gate of the memory cell, and the bit line that is connected to the target memory cell is grounded, which in turn causes electrons from the channel to be injected into the floating gate. During a program operation, the bit line that is connected to the target memory cell is referred to as a selected bit line. Conversely, a bit line that is not connected to a target memory cell during a program operation is referred to as an unselected bit line. In this context, a state of the bit line may refer to whether the bit line is selected or unselected. Otherwise stated, a bit line can be in one of two states, selected or unselected. When electrons accumulate in the floating gate, the floating gate becomes negatively charged and the threshold voltage V_{TH} of the memory cell is raised. The power control circuitry 160 applies the program voltage V_{PGM} on the wordline that is connected to the target memory cell in order for the control gate of the target memory cell to receive the program voltage V_{PGM} and for the memory cell to be programmed. As previously described, in a block, one memory cell in each of the NAND strings share the same word line. During a program operation, the word line that is connected to a target memory cell is referred to as a selected word line. Conversely, a word line that is not connected to a target memory cell during a program operation is referred to as an unselected word line.

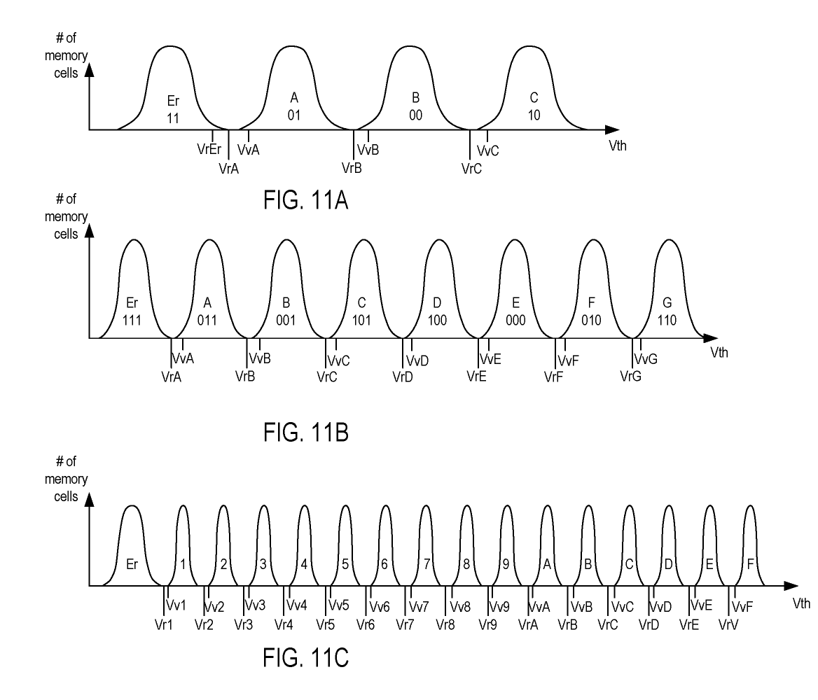

FIGS. 11A-11C are plots of threshold voltage distribution curves for different numbers of bits being stored the memory cells. The threshold voltage distribution curves are plotted for threshold voltage V_{TH} as a function of the number of memory cells. FIG. 11A show threshold voltage distribution curves for memory cells programmed to store two bits of data, FIG. 11B show threshold voltage distribution curves for memory cells programmed to store three bits of data, and FIG. 11C show voltage distribution curves for memory cells programmed to store four bits of data. Similar threshold voltage distribution curves may be generated for memory cells programmed to store numbers of bits other than two, three, and four.

At a given point in time, each memory cell may be a particular one of a plurality of memory states (otherwise referred to as a data state). The memory states may include an erased stated and a plurality of programmed states. Accordingly, at a given point in time, each memory cell may be in the erased state or one of the plurality of programmed states. The number of programmed states corresponds to the number of bits the memory cells are programmed to store. With reference to FIG. 11A, for a memory cell programmed to store two bits, the memory cell may be in an erased state Er or one of three programmed states A, B, C. With reference to FIG. 11B, for a memory cell programmed to store three bits, the memory cell may be in an erased state Er or one of seven programmed states A, B, C, D, E, F, G. With reference to FIG. 11C, for a memory cell programmed to store four bits, the memory cell may be in an erased state Er or one of fifteen programmed states 1, 2, 3, 4, 5, 6, 7, 8, 9, A, B, C, D, E, F. As shown in FIGS. 11A-11C, each voltage distribution curve is associated with the erased state or one of the programmed states.

Additionally, each threshold voltage distribution curve defines and/or is associated with a distinct threshold voltage range that, in turn, defines, is assigned, or is associated with a distinct one of a plurality of predetermined n-bit binary values. As such, determining what threshold voltage V_{TH} a memory cell has allows the data (i.e., the logic values of the bits) that the memory cell is storing to be determined. The specific relationship between the data programmed into the memory cells and the threshold voltage levels of the memory cell depends on the data encoding scheme used for programming the memory cells. In one example, as shown in FIGS. 11A and 11B, a Gray code scheme is used to assign data values to the threshold voltage distribution curves. Under this scheme, for memory cells programmed with two bits of data, the data value “11” is assigned to the range of threshold voltages associated with the erased state Er, the data value “01” is assigned to the range of threshold voltages associated with programmed state A, the data value “00” is assigned to the range of threshold voltages associated with programmed state B, and the data value “10” is assigned to the range of threshold voltages associated with the programmed state C. Similar relationships between data values and memory states can be made for memory cells programmed to store three bits, four bits, or other bits of data.

Prior to performance of a program operation that programs a plurality or group of target memory cells, all of the memory cells of the group subjected to and/or selected to be programmed in the programming operation may be in the erased state. During the programming operation, the power control circuitry 160 may apply the program voltage to a selected word line and in turn the control gates of the target memory cells as a series of program voltage pulses. The target memory cells being programmed concurrently are connected to the same, selected word line. In many programming operations, the power control circuitry 160 increases the magnitude of the program pulses with each successive pulse by a predetermined step size. Also, as described in further detail below, the power control circuitry 160 may apply one or more verify pulses to the control gate of the target memory cell in between program pulses as part of a program loop or a program-verify operation. Additionally, during a programming operation, the power control circuitry 160 may apply one or more boosting voltages to the unselected word lines.

The target memory cells connected to the selected word line will concurrently have their threshold voltage change, unless they have been locked out from programming. When the programming operation is complete for one of the target memory cells, the target memory cell is locked out from further programming while the programming operation continues for the other target memory cells in subsequent program loops. Also, for some example programming operations, the control logic circuitry 154 may maintain a counter that counts the program pulses.

During a program operation to program a group of target memory cells, each target memory cell is assigned to one of the plurality of memory states according to write data that is to be programmed into the target memory cells during the program operation. Based on its assigned memory state, a given target memory cell will either remain the erased state or be programmed to a programmed state different from the erased state. When the control logic 154 receives a program command from the controller 102, or otherwise determines to perform a program operation, the write data in stored in latches included in the read/write circuitry 144. During the programming operation, the read/write circuitry 144 can read the write data to determine the respective memory state to which each of the target memory cells is to be programmed.

As described in further detail below, and as illustrated in FIGS. 11A-11C, each programmed state is associated with a respective verify voltage level Vv. A given target memory cell is programmed in its assigned memory state when its threshold voltage V_{TH} is above the verify voltage Vv associated with the memory state assigned to that target memory cell. As long as the threshold voltage V_{TH} of the given target memory cell is below the associated verify voltage Vv, the control gate of the target memory cell may be subject to a program pulse to increase the target memory cell's threshold voltage V_{TH} to within the threshold voltage range associated with the memory state assigned to the given target memory cell. Alternatively, when the threshold voltage V_{TH} of the given target memory cell increases to above the associated verify voltage level Vv, then programming may be complete for the given target memory cell. As described in further detail below, a sense block 146 may participate in a program-verify operation that determines whether programming for a given memory cell is complete.

As previously mentioned, target memory cells subject to a program operation may also be subject to a verify operation that determines when programming is complete for each of the target memory cells. The verify operation is done in between program pulses, and so the programming operation and the verify operation in performed in an alternating or looped manner. The combination of the programming operation and the verify operation is called a program-verify operation. Accordingly, a program-verify operation includes a plurality of programming operations and a plurality of verify operations that are alternatingly performed. That is, a program-verify operation involves a programming operation followed by a verify operation, followed by another programming operation, followed by another verify operation, and so on until the program-verify operation has no more programming or verify operations to be performed. In addition, a single programming operation of a program-verify operation includes the power control circuitry 160 supplying one or more program pulses to the selected word line for that single programming operation, and a single verify operation of a program-verify operation includes the power control circuitry 160 supplying one or more verify pulses to the selected word line for that single programming operation. Accordingly, a program-verify operation may include the power control circuitry 160 supplying a pulse train or a series of voltage pulses to the selected word line, where the pulse train includes one or more program pulses followed by one or more verify pulses, followed by one or more program pulses, followed by one or more verify pulses, and so on until the program-verify process has no more program or verify pulses for the power control circuitry 160 supply to the selected word line.

A program-verify operation is complete when the verify portion of the program-verify operation identifies that all of the memory cells have been programmed to their assigned threshold voltages V_{TH}. As mentioned, the verify process verifies or determines that a given target memory cell is finished being programmed when the verify process determines that the target memory cell's threshold voltage has increased to above the verify voltage level Vv associated with the memory state to which the target cell is to be programmed.

For some example program-verify operations, all of the target memory cells subject to a program-verify operation are not subject to a single verify operation at the same time. Alternatively, for a single verify operation, only those target memory cells that are assigned to the same memory state are subject to a verify operation. For a single verify operation, target memory cells that are subject to the single verify operation are called selected memory cells or selected target memory cells, and target memory cells that are not subject to the single verify operation are called unselected memory cells or unselected target memory cells. Likewise, for a group of bit lines connected to the target memory cells of a program-verify operation, bit lines connected to the selected memory cells for a single verify operation are called selected bit lines, and bit lines connected to the unselected memory cells for a single verify operation are called unselected bit lines. In this context, a state of the bit line may refer to whether the bit line is selected or unselected. Otherwise stated, a bit line can be in one of two states, selected or unselected.

For each of the verify operations, the power control circuitry 160, or some combination of the power control circuitry 160, the read/write circuitry 144, and the sense blocks 146, may supply voltages at appropriate levels to the selected and unselected word lines and the selected and unselected bit lines in order for a verify operation to be performed for the selected memory cells of the target memory cells subject to the program-verify operation. For clarity, and unless otherwise specified, the combination of the power control circuitry 160, the read/write circuitry 144, and the sense blocks 146 used to bias the selected and unselected word lines and bit lines at appropriate levels during a given memory operation (e.g., a programming operation, a verify operation, a program-verify operation, a read operation, or an erase operation) is herein referred to collectively as voltage supply circuitry. Voltage supply circuitry may refer to the power control circuitry 160, the sense block circuitry 146, other circuit components of the read/write circuitry 144, or any combination thereof.

For performance of a verify operation in a block, the voltage supply circuitry may supply a drain select gate bias voltage V_{SGD} on the drain select gate bias line SGD to the control gates of the drain select gate transistors (e.g., transistors 606 of FIG. 6) and a source select gate bias voltage V_{SGS} on the source select gate bias line SGS to the control gates of the drain select gate transistors (e.g., transistors 608 of FIG. 6) at levels that turn on the drain select gate transistors and the source select gate transistors in response to the voltage supply circuitry supplying voltages at suitable levels on the common source line SL and to the bit lines.

Additionally, the voltage supply circuitry supplies a source line voltage at a cell source voltage level Vcelsrc, otherwise referred to as the cell source voltage Vcelsrc, on the common source line SL. Further, the voltage supply circuitry biases the drain side of the selected bit lines with a high supply voltage VHSA that is higher in magnitude than the cell source voltage Vcelsrc. The difference between the high supply voltage VHSA and the cell source voltage level Vcelsrc may be great enough to allow current to flow from the drain side to the source side of a string that includes a selected target memory cell in the event that the selected target memory cell has a threshold voltage V_{TH} that allows it to conduct a current. During a verify operation, a selected memory cell can be generally characterized as fully conducting, marginally conducting, or non-conducting, depending on the threshold voltage V_{TH} of the selected memory cell. Also, the voltage supply circuitry biases the drain side of the unselected bit lines to the cell source voltage Vcelsrc. By biasing the drain side and the source side of unselected bit lines to the cell source voltage Vcelsrc, the voltage difference between the drain side and source side voltages will not allow current to flow through the NAND string connected to the unselected bit line. Further, the voltage supply circuitry biases the unselected word lines, and in turn the control gates of FGTs coupled to the unselected word lines, to a read voltage Vread. The read voltage is high enough to cause the FGTs coupled to unselected word lines to conduct a current regardless of its threshold voltage V_{TH}. In addition, the voltage supply circuitry biases the selected word line with a control gate reference voltage V_{CGRV}, which may be in the form of one or more verify pulses as previously described. The control gate reference voltage V_{CGRV} may be different for verification of target memory cells of different memory states. For example, the voltage supply circuitry may supply a different control gate reference voltage V_{CGRV} (or a control gate reference voltage V_{CGRV} at different level) when verifying target memory cells programmed to state A than when verifying target memory cells programmed to state B, and so on.

Once the voltage supply circuitry supplies the voltages to the selected and unselected word lines and bit lines, and to the drain select gate transistors, source select gate transistors, drain select gate bias line SGD, and source select gate bias line SGS, a sense block can perform a sense operation that identifies whether a selected target memory cell is conducting, and in turn sufficiently programmed. Further details of the sense operation portion of the verify operation are described in further detail below.

As previously described, the threshold voltage V_{TH} of a memory cell may identify the data value of the data it is storing. For a given read operation in a block, a memory cell from which data is to be read is referred to as a selected memory cell, and a memory cell from which data is not to be read is referred to as an unselected memory cell. So, when data is to be read from a page of memory cells for a particular read operation, those memory cells in the page are the selected memory cells, and the memory cells of the block that are not part of the page are the unselected memory cells. Additionally, a word line connected to the page of selected memory cells is referred to as the selected word line, and the other word lines of the block are referred to as the unselected word lines.

During a read operation to read data stored in target memory cells of a page, the sense blocks 146 may be configured to perform a sense operation that senses whether current is flowing through the bit lines connected to the target memory cells of the page. The voltage supply circuitry may supply voltages on the selected and unselected word lines at appropriate levels that cause current to flow or not to flow based on the threshold voltage V_{TH} of the target memory cells. For some configurations, the level of the voltage supplied to the selected word lines may vary depending on the states of the memory cells.

The voltage supply circuitry may also bias the bit lines so that the high supply voltage VHSA is applied to the drain side of the bit lines and the cell source voltage Vcelsrc is applied to the source side of the bit lines to allow for the current flow, provided that the threshold voltage V_{TH} of the selected memory cell allows for it. For some example read configurations, where the sense block 146 can perform a sense operation for fewer than all of the memory cells of a page. For such configurations, the target memory cells of the page that are subject to and/or that are selected for a given sense operation are referred to as selected memory cells or selected target memory cells. Conversely, the target memory cells of the page that are not subject to and/or that are not selected for the sense operation are referred to as unselected memory cells. Accordingly, bit lines connected to selected target memory cells are referred to as selected bit lines, and bit lines connected to unselected target memory cells are referred to as unselected bit lines. In this context, a state of the bit line may refer to whether the bit line is selected or unselected. Otherwise stated, a bit line can be in one of two states, selected or unselected. The voltage supply circuitry can supply the voltages to the selected and unselected word lines and the selected and unselected bit lines at levels in various combinations and/or in various sequences and/or over various sense operations in order determine the threshold voltages of the target memory cells so that the data values of the data that the target memory cells are storing can be determined.

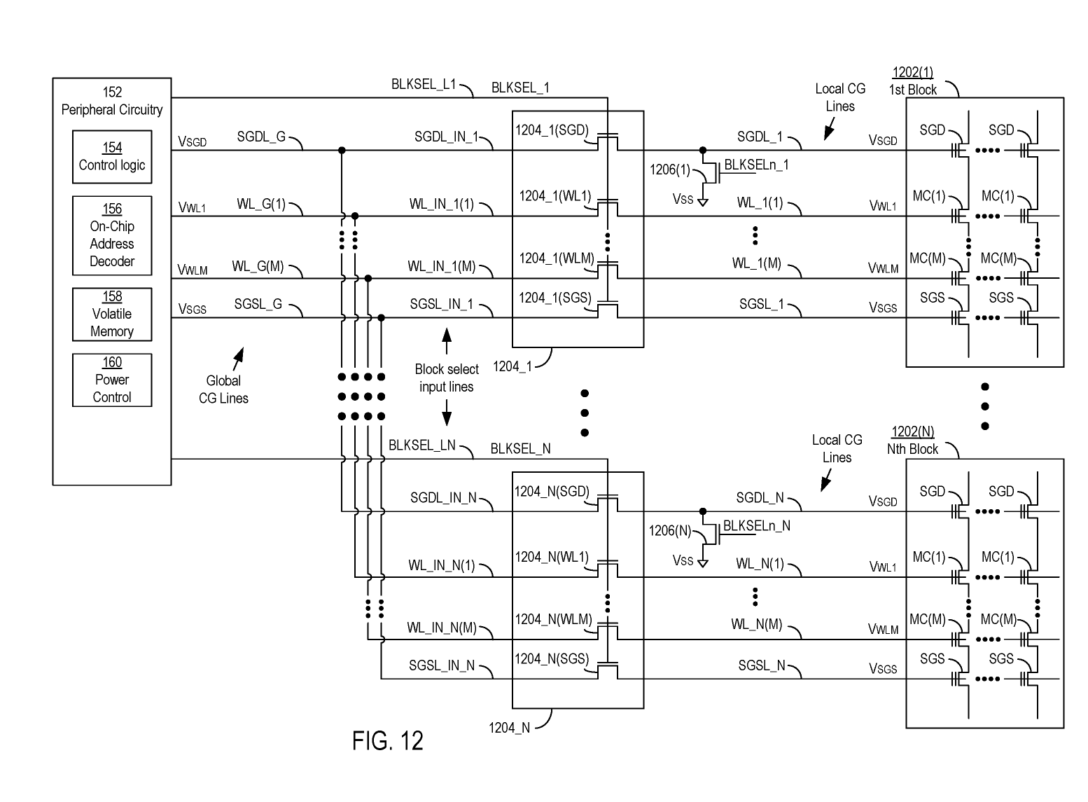

FIG. 12 shows a partial circuit schematic diagram of control gate (CG) voltage communication circuitry that is configured to communicate or supply a set of CG voltages from the peripheral circuitry 152 to an N-number of blocks 1202(1) to 1202(N). The set of CG voltages that the peripheral circuitry 152, such as with the power control circuitry 160, is configured to generate, and that the CG voltage communication circuitry is configured to communicate, may include a drain select gate bias voltage V_{SGD}, a source select gate bias voltage V_{SGS}, and a set of M-number of word line voltages V_{WL1} to V_{WLM}. For some example configurations, the CG voltage communication circuitry is part of the row decoder 148 (FIG. 2B), although in other example configurations, all or some of the components of the CG voltage communication circuitry may be considered separate from the row decider 148. In addition, for some example configurations, the N-number of blocks 1202(1) to 1201(N) may be located in the same plane of a memory die 104, although other configurations may be possible.

For purposes of illustration, each of the blocks 1202(1) to 1202(N) is shown as including a plurality of strings, with each string including an M-number of memory cells MC(1) to MC(M) connected to a drain select gate transistor SGD and a source select gate transistor (SGS). Each of the blocks may include, be connected to, and/or be associated with an associated set of local control gate (CG) lines that are connected to the control gates of the transistors of the associated block. With respect to the block configuration shown in FIG. 12, each set of local CG lines may include a set of M-number of local word lines WL(1) to WL(M) connected to the control gates of the memory cells MC(1) to MC(M), and select gate bias lines, including a drain select gate bias line SGDL connected to the control gates of the drain select gate transistors SGD and a local source select gate bias line SGSL.

So, for example, the control gates of the drain select gate transistors SGD of the first block 1202(1) are connected to a first local drain select gate bias line SGDL_1, and the control gates of the drain select gate transistors SGD of the Nth block 1202(N) are connected to an Nth local drain select gate bias line SGDL_N. In addition, the control gates of the source select gate transistors SGS of the first block 1202(1) are connected to a first local source select gate bias line SGSL_1, and the control gates of the source select gate transistors SGS of the Nth block 1202(N) are connected to an Nth local source select gate bias line SGSL_N.

Also, for a given block, the control gates of the memory cells that are part of the same page of memory cells are connected to the same or a common local word line WL. So, for example, first memory cells MC(1) of a first page of the first block 1202(1) are connected to a first local word line WL_1(1) of the first block 1202(1), Mth memory cells MC(M) of an Mth page of the first block 1202(1) are connected to an Mth local word line WL_1(M) of the first block 1202(1), first memory cells MC(1) of a first page of the Nth block 1202(2) are connected to a first local word line WL_N(1) of the Nth block 1202(N), and Mth memory cells MC(M) of an Mth page of the Nth block 1202(N) are connected to an Nth local word line WL_N(M) of the Nth block 1202(N).

Each local CG line of a given set of local CG line may be configured to receive one of the control gate voltages and supply the local control gate voltage it receives to the control gates of the transistors to which it is connected. So, a local drain select gate bias line SGDL may be configured to receive the drain select gate bias voltage V_{SGD} and supply the drain select gate bias voltage V_{SGD} to the control gates of the drain select gate transistors SGD to which it is connected, a local source select gate bias line SGSL may be configured to receive the source select gate bias voltage V_{SGS} and supply the source select gate bias voltage V_{SGS} to the control gates of the source select gate transistors SGS to which it is connected, and each of the M-number of local word lines WL may be configured to receive a respective one of the word lines voltages V_{WL1} to V_{WLM} and supply the respective one of the word line voltages V_{WL1} to V_{WLM} to the control gates of the respective memory cells MC to which each of the local word lines WL are connected. In some example configurations, all or at least a portion of the local CG lines may be considered part of the CG voltage communication circuitry.

The peripheral circuitry 152, such as with the control logic 154 and/or the on-chip address decoder 156, may be configured to identify or select one or more of the blocks 1202 that are to receive the CG voltages at a given point in time or for a predetermined period of time. When the peripheral circuitry 152 selects a given block, the given block is configured to receive, via its associated local CG lines, the CG voltages generated by the peripheral circuitry 152. Conversely, for a given block that is not selected by the peripheral circuitry 152, that block is not configured to receive the CG voltages generated by the peripheral circuitry. For the period of time that a given block is selected, the given block is referred to as a selected block. Likewise, for a period of time that a given block is unselected, the given block is referred to as an unselected block.

The peripheral circuitry 152 may be configured to change which of the blocks 1202(1) to 1202(N) are selected blocks and which are unselected blocks at different periods of time. For example, during a first time period, the peripheral circuitry 152 may identify a first set of one or more of the N-number of blocks 1202(1) to 1202(N) as selected, and the other of the N-number of blocks 1202(1) to 1202(N) as unselected. During a second (e.g., subsequent) time period, the peripheral circuitry 152 may identify a second set of one or more of the N-number of blocks 1202(1) to 1202(N) as selected, and the other of the N-number of blocks 1202(1) to 1202(N) as unselected, where at least one of the selected blocks in the second time period is different than at least one of the selected blocks in the first time period.

In addition, the peripheral circuitry 152 may be configured to select or identify which blocks are selected and which are unselected based on memory operations (e.g., read program, verify, erase) to be performed on the blocks 1202(1) to 1202(N). In particular, the peripheral circuitry 152 may be configured to identify a memory block on which a memory operation is to be performed, and in response, select that block and/or identify that block as being a selected block. For example, the peripheral circuitry 152 may identify that a first memory operation is to be performed on the first block 1202(1), and in response, select the first block 1202(1) and/or identify the first block 1202(1) as a selected block. In turn, the first peripheral circuitry 152 may generate the CG voltages for performance of the first memory operation, and the first block 1202(1) may receive the CG voltages via its local CG lines for performance of the first memory operation. Subsequently, the peripheral circuitry 152 may identify that a second memory operation is to be performed on the Nth block 1202(N), and in response, select the Nth block 1202(N) and/or identify the Nth block 1202(N) as a selected block. In turn, the peripheral circuitry 152 may generate the CG voltages for performance of the second memory operation, and the Nth block 1202(N) may receive the CG voltages via its local CG lines for performance of the second memory operation.

For some example configurations, the peripheral circuitry 152 may be configured to select only one of the blocks 1202(1) to 1202(N) at a time. Otherwise stated, for a given time period, the peripheral circuitry 152 may identify one of the blocks 1202(1) to 1202(N) as selected, and all of the other of the blocks 1202(1) to 1202(N) as unselected. For these example configurations, at a given moment in time, only one of the blocks 1202(1) to 1202(N) is configured to receive the CG voltages from the peripheral circuitry 152. In other example configurations, the peripheral circuitry 152 may be configured to select more than one of the blocks 1202(1) to 1202(N) at a time, such that multiple blocks can simultaneously be selected blocks and be configured to receive the control gate voltages.

The CG voltage communication circuitry may include a set of global CG lines, including a global drain select gate bias line SGDL_G, a set of M-number of global word lines WL_G(1) to WL_G(M), and a global source select gate bias line SGSL_G. The power control circuitry 160 may be configured to output the CG voltages to the blocks 1202(1) to 1202(N) via the global CG lines. In particular, the power control circuitry 160 may be configured to output the drain select gate bias voltage V_{SGD} onto the global drain select gate bias line SGDL_G, the word line voltages V_{WL1} to V_{WLM} respectively onto the global word lines WL_G(1) to WL_G(M), and the source select gate bias voltage V_{SGS} onto the global source select gate bias line SGSL_G.

The CG voltage communication circuitry may further include block select switching circuits 1204 that enable communication of the CG voltages from the global CG lines to the local CG lines of the selected blocks. Each block select switching circuit 1204 may be implemented as an n-channel metal-oxide-semiconductor field-effect transistor (NMOS transistor), although other configurations may be possible. In addition or alternatively, each block select switching circuit 1204 may be configured and/or referred to as a pass transistor.

The block select switching circuits 1204 may be organized or configured into sets or groups, and each set of block select switching circuits 1204 may be associated with a respective one of the blocks 1202(1) to 1202(N). So, for example, a first set of block select switching circuits 1204_1 is associated with the first block 1202(1), an Nth set of block select switching circuit 1204_N is associated with the Nth block 1202(N), and so on.

In turn, each set of block select switching circuits 1204 may be associated with and connected to an associated set of local CG lines. So, for example, the first set of block select switching circuits 1204_1 is associated with the first set of local CG lines SGDL_1, WL_1(1) to WL_1(M), and SGSL_1; the Nth set of block select switching circuits 1204_N is associated with the Nth set of local CG lines SGDL_N, WL_N(1) to WL_N(M), and SGSL_N; and so on.

In addition, each set of block select switching circuits 1204 may be configured to connect an associated set of local CG lines to the global CG lines. So, for example, the first set of block select switching circuits 1204_1 may be configured to connect the first set of local CG lines SGDL_1, WL_1(1) to WL_1(M), and SGSL_1 to the global CG lines SGDL_G, WL_G(1) to WL_G(M), SGSL_G; the Nth set of block select switching circuits 1204_N may be configured to connect the Nth set of local CG lines SGDL_N, WL_N(1) to WL_N(M), and SGSL_N to the global CG lines SGDL_G, WL_G(1) to WL_G(M), SGSL_G; and so on.

In addition, each block select switching circuit 1204 in a set is configured to connect to and receive a CG voltage from one of the global CG lines. So, a given ith set of block select switching circuits 1204_i may include an ith SGD block select switching circuit 1204_i(SGD) that is configured to connect to the global drain select gate bias line SGDL_G and receive the drain select gate bias voltage V_{SGD} from the global drain select gate bias line SGDL_G; an ith set of M-number of word line (WL) block select switching circuits 1204_i(WL1) to 1204_i(WLM), each configured to connect to a respective one of the M-number of global word lines WL_G(1) to WL_G(M) and receive a respective one of the word lines voltage V_{WL1} to V_{WLM} from a respective one of the global word lines WL_G(1) to WL_G(M); and an ith SGS block select switching circuit 1204_i(SGS) that is configured to connect to the global source select gate bias line SGSL_G and receive the source select gate bias voltage V_{SGS} from the global source select gate bias line SGSL_G. As used herein, a block select switching circuit in a set corresponds to a given global CG line if it is configured to connect to and receive a CG voltage from the given global CG line.

Also, each block select switching circuit 1204 in an ith set of block select switching circuits 1204_i is configured to connect to and supply a CG voltage it receives to a corresponding one of associated local CG lines. Accordingly, in a given ith set of block select switching circuits 1204_i, a block select switching circuits corresponds to local CG line if it is configured to connect to and/or supply a CV voltage to it. Accordingly, in a given ith set of block select switching circuits 1204_i, the ith SGD block select switching circuit 1204_i(SGD) is configured to connect to, supply the drain select gate bias voltage V_{SGD} to, and thus corresponds to, the local drain select gate bias line SGDL_i of an associated ith set of local CG lines; each of the M-number of WL switching circuits 1204_i(WL1) to 1204_i(WLM) is configured to connect to, supply a respective word line voltage V_{WL1} to V_{WLM} to, and thus corresponds to, a respective one of the local word lines WL_i(1) to WL_i(M); and the ith SGS block select switching circuit 1204_i(SGS) is configured to connect to, supply the source select gate bias voltage V_{SGS} to, and thus corresponds to, the local source select gate bias line SGSL_i of an associated ith set of local CG lines.

Also, each block select switching circuit 1204 of a set is configured to connect a corresponding local CG lines with a corresponding global CG line. In general, as used herein, two CG lines correspond to each other if they are configured to communicate the same CG voltage. In that respect, in each ith set of block select switching circuits 1204_i, the ith SGD block select switching circuit 1204_i(SGD) is configured to connect its corresponding local drain select gate bias line SGDL_i with its corresponding global drain select gate bias line SGDL_G; the ith SGS block select switching circuit 1204_i(SGS) is configured to connect its associated local source select gate bias line SGSL_i with its corresponding global source select gate bias line SGSL_G; and the M-number word line (WL) block select switching circuits 1204_i(WL1) to 1204_i(WLM) are each configured to connect its corresponding local word line WL_i with its corresponding global word line WL_G.

Also, as used herein, the term “global” is used to identify a component that is not associated with any one particular block, whereas the term “local” is used to identify a component that is associated with a particular block. Accordingly, through control of the block select switching circuit 1204, a global CG line can be connected to and supply an associated CG voltage to any of its corresponding local CG lines. Similarly, any of the local CG lines can be connected to a corresponding CG line to receive an associated CG voltage.

Additionally, each of the global CG lines may be configured to branch off into respective block select input lines so that each of the sets of the block select switching circuits 1204_1 to 1204_N can receive the CG voltages. Accordingly, the global drain select gate bias line SGDL_G is configured to branch off into an N-number of SGD block select input lines SGDL_IN_1 to SGDL_IN_N, each configured to connect the global drain select gate bias line SGDL_G to a corresponding one of the SGD block select switching circuits 1204_1(SGD) to 1204_N(SGD), and supply the drain select gate bias voltage V_{SGD} from the global drain select gate bias line SGDL_G to the corresponding one of the SGD block select switching circuits 1204_1(SGD) to 1204_N(SGD). Additionally, for each of the global word lines WL_G(1) to WL_G(M), each jth global word line WL_G(j) is configured to branch off into a respective N-number of block select WL input lines WL_IN_1(j) to WL_IN_N(j). For a given jth global word line WL_G(j), each ith WL input supply line is configured to connect the jth global word line WL_G(j) to a corresponding ith WL block select switching circuit 1204_i(WLj) and supply the jth word line voltage V_{WLj} to the corresponding ith WL block select switching circuit 1204_i(WLj). Also, the global source select gate bias line SGSL_G is configured to branch off into an N-number of block select SGS input lines SGSL_IN_1 to SGSL_IN_N, each configured to connect the global source select gate bias line SGSL_G to a corresponding one of the SGS block select switching circuits 1204_1(SGS) to 1204_N(SGS), and supply the source select gate bias voltage V_{SGS} from the global source select gate bias line SGSL_G to the corresponding one of the SGS block select switching circuits 1204_1(SGS) to 1204_N(SGS).

The peripheral circuitry 152, such as with the control logic 154 and/or the on-chip address decoder 156, may be configured to select and unselect blocks by outputting block select signals BLKSEL to the sets of block select switching circuits 1204. In particular, the peripheral circuitry 152 may be configured to output a plurality of block select signals BLKSEL, each to a respective one of the sets of block select switching circuits 1204. For example, the peripheral circuitry 152 may be configured to output a first block select signal BLKSEL_1 to the first set of block select switching circuits 1204_1, an Nth block select signal BLKSEL_N to the Nth set of block select switching circuits 1204_N, and so on.

A given ith block select signal BLKSEL_i is associated with an ith block 1202(i) that is, in turn, associated with the ith set of block select switching circuits 1204_i configured to receive the given ith block select signal BLKSEL_i. So, for example, the first block select signal BLKSEL_1 is associated with the first block 1202(1), the Nth block select signal BLKSEL_N is associated with the Nth block 1202(N), and so on.

The peripheral circuitry 152 may be configured to output each of the block select signals BLKSEL_1 to BLKSEL_N at a first level (e.g., a first voltage level) or at a second level (e.g., a second voltage level). The peripheral circuitry 152 may be configured to output a given ith block select signal BLKSEL_i at the first level when it selects an associated ith block 1202(i), identifies the ith block 1202(i) as being a selected block, and/or wants the ith block 1202(i) to be a selected block. Accordingly, the first level at which the peripheral circuitry 152 generates an ith block select signal BLKSEL_i indicates that the associated ith block 1202(i) is a selected block. In addition, the peripheral circuitry 152 may be configured to output a given ith block select signal BLKSEL_i at the second level when it unselects an associated ith block 1202(i), identifies the ith block 1202(i) as being an unselected block, and/or wants the ith block 1202(i) to be an unselected block. Accordingly, the second level at which the peripheral circuitry 152 generates an ith block select signal BLKSEL_i indicates that the associated ith block 1202(i) is an unselected block.

For a given ith block select signal BLKSEL_i, the first level may be a level that activates the ith block select switching circuits 1204_i, and the second level may be a level that deactivates the ith block select switching circuits 1204_i. As used herein, when a block select switching circuit 1204 is activated or in an activated state, the block switching circuit 1204 is turned on, closed, or otherwise in a state or configuration that connects, including electrically connects, its corresponding global CG line to its corresponding local CG line. Additionally, when activated or in the activated state, the block switching circuit 1204 is configured to receive an associated CG voltage from its corresponding global CG line and supply the received associated CG voltage to its corresponding local CG line. Further, as used herein, when a block select switching circuit 1204 is deactivated or in a deactivated state, the block switching circuit 1204 is turned off, open, or otherwise in a state or configuration that disconnects, including electrically disconnects, its corresponding global CG line from its corresponding local CG line. Additionally, when deactivated or in the deactivated state, the block switching circuit 1204 is configured to not supply an associated CG voltage to its corresponding local CG line.

In addition, in the example configuration shown in FIG. 12, the peripheral circuit 152 is configured to output each ith block select signal BLKSEL_i to each of the block select switching circuits 1204 in an associated ith set. For example, the peripheral circuit 152 is configured to output the first block select signal BLKSEL_1 to each of the first SGD block select switching circuit 1204_1(SGD), the M-number of WL block select switching circuits 1204_1(WL1) to 1204_1(WLM), and the first SGS block select switching circuit 1204_1(SGS). Likewise, the peripheral circuit 152 is configured to output the Nth block select signal BLKSEL_N to each of the Nth SGD block select switching circuit 1204_N(SGD), the M-number of WL block select switching circuits 1204_N(WL1) to 1204_N(WLM), and the Nth SGS block select switching circuit 1204_N(SGS). Accordingly, for this example configuration, the peripheral circuit 152 is configured to output a given ith block select signal BLKSEL_i at the first level or the second level in order to collectively activate or deactivate an associated ith set of block select switching circuits 1204_i.

Further, the peripheral circuitry 152 is configured to output each of the block select signals BLKSEL_1 to BLKSEL_N on a respective one of a plurality of block select lines BLKSEL_L1 to BLKSEL_LN. So, for example, the peripheral circuitry 152 is configured to output the first block select signal BLKSEL_1 on a first block select line BLKSEL_L1, the Nth block select signal BLKSEL_N on an Nth block select line BLKSEL_LN, and so on. The peripheral circuitry 152 may be configured to collectively activate or deactivate a given ith set of block select switching circuits 1204_i by supplying the associated ith block select signal at either the first level or the second level via the ith block select line BLKSEL_i.

In general, when the peripheral circuitry 152 wants to select a given ith block 1202(i), it may output the associated block select signal BLK_SEL_i on the ith block select line BLKSEL_Li at the first level to activate the ith set of block select switching circuits 1204_i. When the ith set of block select switching circuits 1204_i are activated, the peripheral circuitry 152 may output the control gate voltages V_{SGD}, V_{WL1} to V_{WLM}, V_{SGS} to the ith local CG lines via the global CG lines, the ith input supply lines, and the ith set of block select switching circuits 1204_i. In turn, the ith local CG lines may supply the control gate voltages V_{SGD}, V_{WL1} to V_{WLM}, V_{SGS} to the control gates of the transistors to which they are connected. Additionally, when the peripheral circuitry 152 wants to unselect a given ith block 1202(i), it may output the associated block select signal BLK_SEL_i on the ith block select line BLKSEL_Li at the second level to deactivate the ith set of block select switching circuits 1204_i. In the event that the peripheral circuitry 152 is generating the control gate voltages V_{SGD}, V_{WL1} to V_{WLM}, V_{SGS}, the ith unselected block 1202(i) may not receive the control gate voltages V_{SGD}, V_{WL1} to V_{WLM}, V_{SGS} from the peripheral circuitry 152 since its associated ith set of block select circuits 1204_i are in a deactivated state.

Additionally, as shown in FIG. 12, a plurality of SGD grounding transistors 1206(1) to 1206(N) may each be in connected in shunt with a respective one of the local drain select gate bias lines SGDL_1 to SGDL_N. For example, a first SGD grounding transistor 1206(1) may be connected in shunt with the first local drain select gate bias line SGDL_1, an Nth SGD grounding transistor 1206(N) may be connected in shunt with the Nth local drain select gate bias line SGDL_N, and so on. In an example configuration shown in FIG. 12, each of the plurality of SGD grounding transistors 1206(1) to 1206(N) may be configured as an NMOS transistor having a drain terminal connected to an associated one of the local drain select gate bias lines SGDL_1 to SGDL_N, a source terminal connected to a low voltage reference SS at a low voltage level V_{SS}, and a gate terminal configured to receive an associated inverse block select signal BLKSELn. Each of SGD grounding transistors 1206(1) to 1206(N) may be configured to turn on and turn off.

When a given ith SGD grounding transistor 1206(i) is turned on, the ith SGD grounding transistor 1206(i) is configured to connect the ith local drain select gate bias line SGDL_i to the low voltage reference SS and bias the ith local drain select gate bias line SGDL_i to the low reference voltage V_{SS}. Alternatively, when the ith SGD grounding transistor 1206(i) is turned off, the ith local drain select gate bias line SGDL_i is floating with respect to the low voltage reference SS. In other words, when the ith SGD grounding transistor 1206(i) is turned off, the ith SGD grounding transistor does not operate to bias the ith local drain select gate bias line SGDL_i to the low reference voltage V_{SS}. Whether the ith SGD grounding transistor 1206(i) is turned on or turned off depends on the level of the ith inverse block select signal BLKSELn_i. For some example configurations, the low voltage reference SS is ground reference, with the low reference voltage V_{SS} being a ground reference voltage, although other low reference voltages at other voltage levels may be possible.

The level of a given ith inverse block select signal BLKSELn_i may be the inverse of the level of the ith block select signal BLKSEL_i. Accordingly, when the ith block select signal BLKSEL_i is at the first level, the ith inverse block select signal BLKSELn_i is at the second level. Conversely, when the ith block select signal BLKSEL_i is at the second level, the ith inverse block select signal BLKSELn_i is at the first level.

In a particular example configuration, the ith inverse block select signal BLKSELn_i at the first level turns on the ith SGD grounding transistor 1206(i), and the ith inverse block select signal BLKSELn_i at the second level turns off the ith SGD grounding transistor 1206(i). Accordingly, when the peripheral circuitry 152 outputs an ith block select signal BLKSEL_i at the first level to select an ith block 1202(i), the ith inverse block select signal BLKSELn_i turns off the ith SGD grounding transistor 1206(i) so that the ith local drain select gate bias line SGDL_i is floating with respect to the low voltage reference SS. Alternatively, when the peripheral circuitry 152 outputs an ith block select signal BLKSEL_i at the second level to unselect an ith block 1202(i), the ith inverse block select signal BLKSELn_i turns on the ith SGD grounding transistor 1206(i) so that the ith SGD grounding transistor 1206(i) bias the ith drain select gate line SGDL_i to the low reference voltage V_{SS}.

In addition, each of the N-number of blocks 1202(1)-1202(N) may have an associated transfer area or region (also referred to as a hookup area region) that includes at least some of the CG voltage communication circuitry. In a particular example configuration, each ith transfer associated with an ith block 1202(i) may include at least a portion of the CG voltage communication circuitry that is configured to communicate or supply the CG voltages to the ith block 1202(i). For example, a given ith transfer region may include the ith set of block select switching circuits 1204_i associated with the ith block 1202(i). Additionally, the given ith transfer region may include at least a portion of the ith local CG lines SGDL WL_i(1) to WL_i(M), and SGSL_i. Also, for some example configurations, a given ith transfer region may include the ith grounding transistor 1206(i) and/or the ith block select input lines SGDL_IN_i, WL_IN_i(1) to WL_IN_i(M), SGSL_IN_1. In addition or alternatively, one or more transfer regions may include a portion of the global CG lines SGDL_G, WL_G(1) to WL_G(M), SGSL_G.

Physically or structurally, as a component of a memory die 104 (i.e., an integrated circuit), a transfer region may be a three-dimensional integrated circuit structure that includes one or more metal layers in which the CG lines may be disposed. The metal layers may be separated by a dielectric material (e.g., dielectric layers) such as silicon oxide or some other dielectric material. A transfer region may also include additional materials to form the active and passive components of the CG voltage communication circuitry, such as the block select switching circuits 1204, for example.

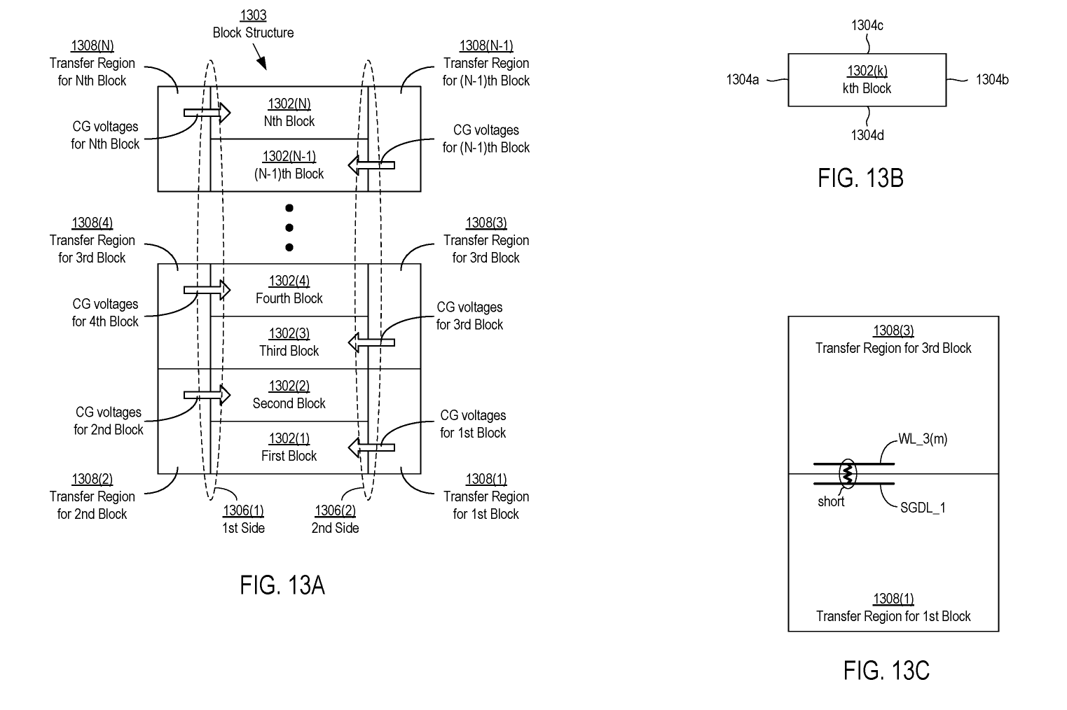

FIG. 13A shows a top view of an example structural layout of an N-number of blocks 1302(1) to 1302(N), which may be representative of the blocks 1202(1) to 1202(N) of FIG. 12. The N-number of blocks 1302(1) to 1302(N) in combination may be referred to as a block structure 1303. In a particular example configuration, the blocks 1302(1) to 1302(N) may be included in the same plane of a memory die 104.

FIG. 13B shows a top view of a kth block 1302(k) in isolation, which may be representative of any of the N-number of blocks 1302(1) to 1302(N). Each of the blocks 1302(1) to 1302(N) may have an outer boundary or perimeter. The top views in FIGS. 13A and 13B show each of the blocks as being generally rectangular in shape, and so for such example configurations, the outer boundary or perimeter of each of the blocks 1302(1) to 1302(N) may include or be defined by four sides. For example, FIG. 13B shows the outer boundary or perimeter of the kth block 1302(k) as including a first side 1304a, a second side 1304b, a third side 1304c, and a fourth side 1304d. Certain sides defining the outer boundary may oppose each other. For example, in FIG. 13B, the first and second sides 1304a, 1304b oppose each other, and the third and fourth sides 1304c, 1304d oppose each other.

As shown in FIG. 13A, the N-number of blocks 1302(1) to 1302(N) are physically oriented or aligned relative to each other such that they form a line of blocks (e.g., a column of blocks). In the line, certain blocks are physically adjacent to certain other blocks. Two blocks of the N-number of blocks 1302(1) to 1302(N) are physically adjacent to each other if there are no blocks disposed in between them. For example, the first block 1302(1) and the second block 1302(2) are physically adjacent to each other, and the second block 1302(2) and the third block 1302(3) are physically adjacent to each other.

Through their physical orientation, the N-number of blocks 1302(1) to 1302(N) as a whole may have an outer boundary or perimeter that includes a first side 1306(1) and a second side 1306(2). The first and second sides 1306(1), 1306(2) oppose each other. Corresponding first sides 1304a of the N-number of blocks 1302(1) to 1302(N) may make up or form the first side 1306(1), and corresponding second sides 1304b of the N-number of blocks 1302(1) to 1302(N) may make up or form the second side 1306(2).

FIG. 13A further shows an N-number of transfer regions 1308(1) to 1308(N) adjacent to the first and second sides 1306(1), 1306(2) of the block structure. Each ith transfer region 1308(i) is associated with an ith th block. So, for example, the first transfer region 1308(1) is associated with the first block 1302(1), the second transfer region 1308(2) is associated with the second block 1302(2), and so on. As indicated by the arrows, each ith transfer region 1308(i) is configured to communicate or supply CG voltages to its associated ith block 1302(i). To communicate or supply the CG voltages, each ith transfer region may include a portion of the CG voltage communication circuitry, including at least a portion of the CG voltage communication circuitry that is associated with the ith block 1302(i), as previously described.

In the example configuration shown in FIG. 13A, the transfer regions 1308(1) to 1308(N) may be disposed adjacent to and/or along both of the first and second sides 1306(1), 1306(2) of the block structure 1303. The transfer regions 1308(1) to 1308(N) may be disposed on and/or adjacent to both sides because the total amount of space or volume that each of the transfer regions 1308(1) to 1308(N) needs to include all of their associated CG voltage communication circuitry components may be too large for all of the transfer regions 1308(1) to 1308(N) to be disposed on only one of the sides 1306(1), 1306(2).

Additionally, as shown in FIG. 13A, for a given pair of physically adjacent blocks, their associated pair of transfer regions may be disposed on both sides 1306(1), 1306(2), with one of the transfer regions being disposed adjacent to the first side 1306(1), and the other of the transfer regions being disposed adjacent to the opposing second side 1306(2). For example, for the physically-adjacent first and second blocks 1302(1), 1302(2), the associated first transfer region 1308(1) is disposed adjacent to the second side 1306(2) and the associated second transfer region 1308(2) is disposed adjacent to the first side 1306(1).

Among transfer regions that are disposed on or adjacent to the same side of the block structure 1303—either the first side 1306(1) or the second side 1306(2)—certain transfer regions may be physically adjacent to each other. Herein, two transfer regions are physically adjacent to each other if they are located on the same side of the block structure 1303, and no other transfer region is disposed in between them. So, for example with reference to FIG. 13A, the first and third transfer regions 1308(1), 1308(3) are physically adjacent to each other, and the second and fourth transfer regions 1308(2), 1308(4) are physically adjacent to each other.

In some example configurations, two CG lines associated with two different blocks can be close enough in proximity to each other that a short or a path of relatively low resistance may form between the two CG lines. Such a short may be caused by degradation in the dielectric material between the two CG lines, for example. Additionally, the short may be manifested by leakage current that flows between the two lines. A most likely occurrence for a short between two CG lines associated with two different blocks is where the two CG lines are disposed in physically adjacent transfer regions.

FIG. 13C illustrates an example situation of a short (or relative low resistance path) between a first local drain select gate bias line SGDL_1 associated with the first block 1302(1) and an mth local word line WL_3(m) associated with the third block 1302(3). For illustration purposes, in FIG. 13C, the first drain select gate bias line SGDL_1 is shown as being disposed in the first transfer region 1308(1) associated with the first block 1302(1) and the mth local word line WL_3(m) is shown as being disposed in the third transfer region 1308(3) associated with the third block 1302(3). In actual implementation, however, an actual or express boundary separating the first and third transfer regions 1308(1), 1308(3) may not be physically present.

In the event that a short exists between a local drain select gate bias line associated with a first block and a local word line associated with a second block, a memory operation (e.g., a program operation) performed on the second block that involves suppling a relatively high voltage on the local word line may disturb one or more drain select gate transistors of the first block that are connected to the local drain select gate bias line. The drain select gate transistors are disturbed in that their threshold voltages may be increased as a result of the supply of the relatively high voltage. In the event that the threshold voltages are increased to above a maximum read voltage level that the peripheral circuitry 152 is configured to supply to the local drain select gate bias line, the peripheral circuitry 152 may be unable to read data stored in memory cells of the first block. Thus, if a short exists between a local drain select gate bias line of the first block and a local word line of the second block, the peripheral circuitry 152, and in turn the controller 102 (FIG. 2A), may want to know of the short before programming data into the first block, the second block, or both.

The following describes inter-block leakage current detection processes that the peripheral circuitry 152 may be configured to perform in order to detect shorts between a local select gate bias line associated with one block and one or more word lines associated with one or more other blocks. The leakage current detection processes are referred to as “inter-block” in that they are performed to detect leakage current caused by shorts between CG lines associated with different blocks. Such inter-block leakage current detection processes may be in contrast to other “intra-block” leakage current detection processes, which are performed to detect for shorts between CG lines associated with the same block.

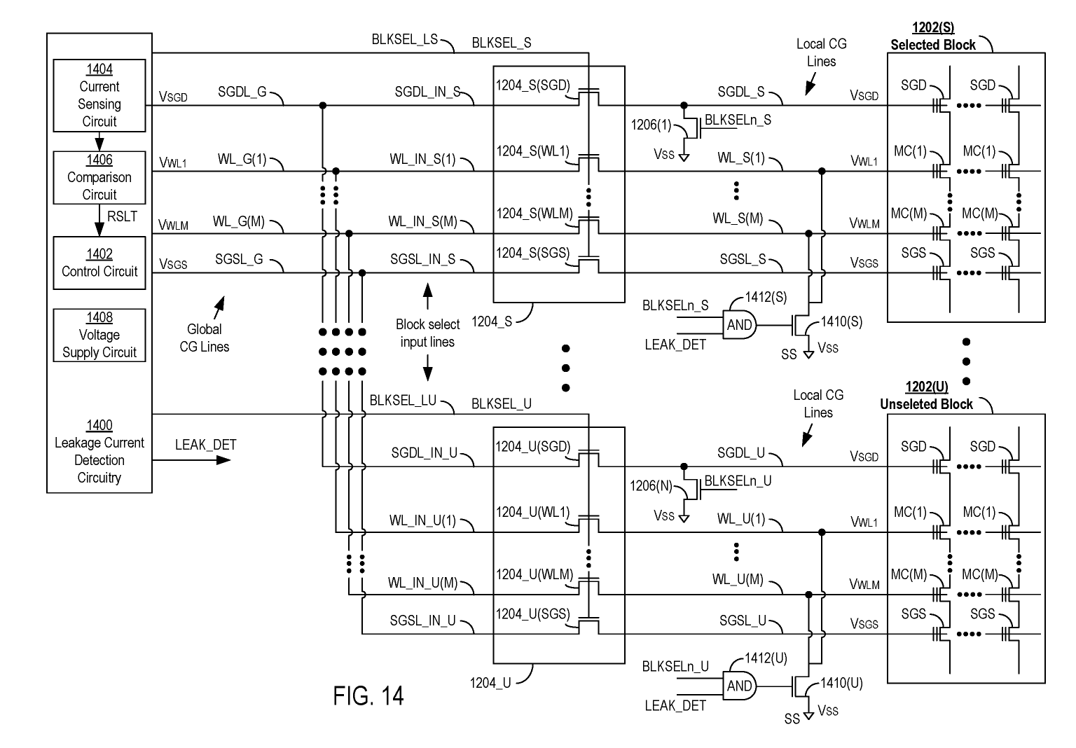

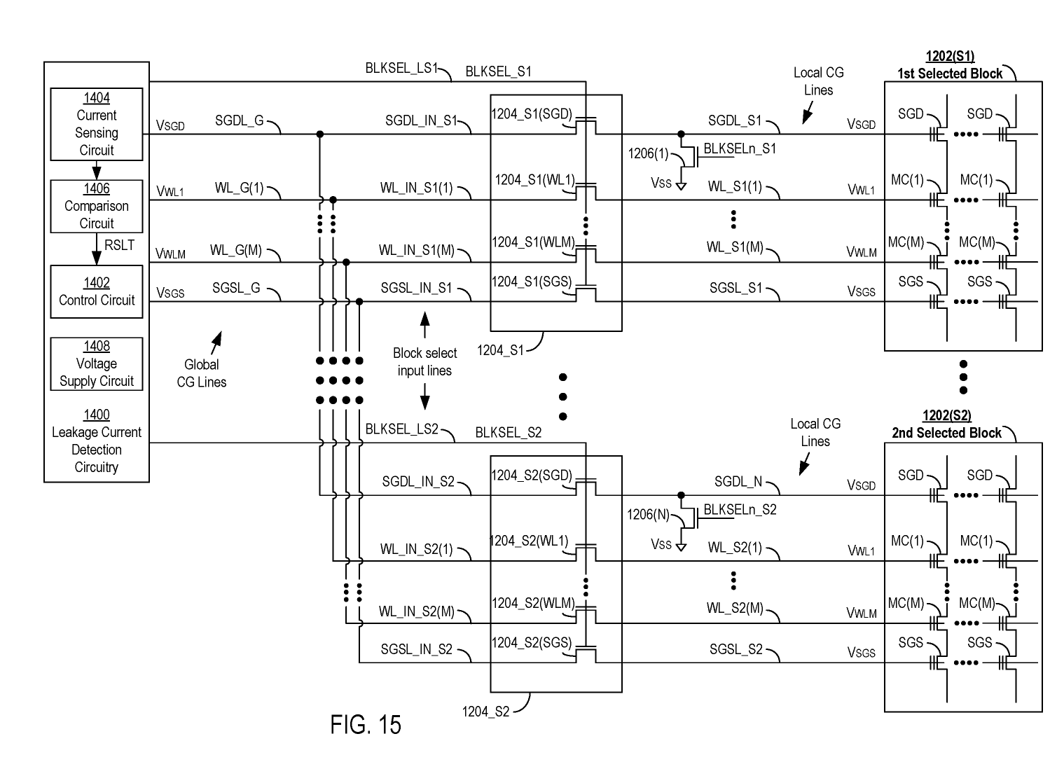

Referring to FIGS. 14 and 15, a first example inter-block leakage current detection process is described with reference to FIG. 14, and a second example inter-block leakage current detection process is described with reference to FIG. 15. To perform the example inter-block leakage current detection processes, the peripheral circuitry 152 may include leakage current detection circuitry 1400 that includes a control circuit 1402 configured to control operation of the inter-block leakage current detection processes, a current sensing circuit 1404 configured to sense and/or monitor for leakage current during the inter-block leakage current detection processes, a comparison circuit 1406 that is configured to compare an amount of leakage current with a threshold current level, and a voltage supply circuit 1408 configured to supply CG voltages to the CG lines of the blocks for performance of the inter-block leakage current detection processes.

For some example configurations, each of the control circuit 1402, the current sensing circuit 1404, the comparison circuit 1406, and the voltage supply circuit 1408 may be components of one or more of the control logic 154, the on-chip address decoder 156, the volatile memory 158, or the power control circuit 160. In other example configurations, one or more of the circuits may be considered separate from the control logic 154, the on-chip address decoder 156, the volatile memory 158, and/or the power control circuit 160.

In both example inter-block leakage current detection processes, a first switching circuit is configured to bias a select gate bias line of a first block with a first leakage detection voltage, and a second switching circuit is configured to bias one or more word lines of a second block with a second leakage detection voltage. Also, in both example inter-block leakage current detection processes, the first block is a selected block. Additionally, in the first example leakage current detection process, the second block is an unselected block, and the second switching circuit is a biasing transistor that is configured to bias the one or more word lines to the low reference voltage V_{SS}. In the second example leakage current detection process, the second block is a selected block, and the second switching circuit is a block select switching circuit associated with the second block. The block select switching circuit is configured to bias the one or more word lines by receiving the second leakage detection voltage from the voltage supply circuit 1408, and supplying the second leakage detection voltage it receives to supply to the one or more word lines of the second block.

Both the first leakage current detection process and the second leakage current detection process are described with the drain select gate bias line being the select gate bias line that is biased with the first leakage detection voltage. However, for other example leakage current detection processes, the source select gate bias line may be the select gate bias line that is biased with the first leakage detection voltage.

Also, as used herein, the terms “leakage detection voltage” and “a CG voltage at a leakage detection level” mean the same and/or are used interchangeably. So, for example, the phrase “the voltage supply circuitry 1408 supplying a first leakage detection voltage to a drain select gate bias line” means the same as the phrase “the voltage supply circuitry 1408 supplying a drain select gate bias voltage V_{SGD} at a first leakage detection level to the drain select gate bias line.” Likewise, the phrase “the block select gate switching circuit 1204 biasing a drain select gate bias line with a first leakage detection voltage” may mean the same as the phrase “the block select gate switching circuit 1204 biasing a drain select gate bias line with a drain select gate bias voltage V_{SGD} at a first leakage detection level.”

Additionally, the CG voltage communication circuitry and the blocks shown in FIGS. 14 and 15 correspond to those shown in FIG. 12. Accordingly, the numbers and labels used to designate the CG communication circuitry and the blocks shown in FIGS. 14 and 15 are the same as or similar to those used in FIG. 12, where appropriate.

With particular reference to FIG. 14, for performance of the first example leakage current detection process, the control circuit 1402 may be configure to select one of the blocks 1202(1) to 1202(N) and unselect at least one of the other blocks 1202(1) to 1202(N). In addition, the control circuit 1402 may be configured to output a leakage detection LEAK_DET that causes one or more local word lines associated with the unselected block to connect to the low voltage reference SS and be biased to the low reference voltage V_{SS}. Additionally, the voltage supply circuit 1408 may supply the drain select gate bias voltage V_{SGD} at the first leakage detection voltage level to local drain select gate bias line associated with the selected block. The control circuit 1402 may control the first leakage current detection process so that the local drain select gate bias line associated with the selected block is biased to the first leakage detection voltage and the local word lines associated with the unselected block are biased to the low reference voltage V_{SS} for a predetermined time period. During this time period, the current sensing circuit 1404, which is connected to the global drain select gate bias line SGDL_G, may sense and/or or monitor for leakage current flowing in the global drain select gate bias line SGDL_G.

In further detail, the control circuit 1402 may be configured to identify one of the blocks 1202(1) to 1202(N) as a selected block and at least one of the other blocks 1202(1) to 1202(N) as an unselected block. As used herein, the letter “S” is used to denote “selected” and the letter “U” is used to denote “unselected.” Accordingly, as shown in FIG. 14, the label “1202(S)” denotes a selected block, and “1202(U)” denotes an unselected block for the first example leakage current detection process.

In response to identifying the selected block 1202(S), the control circuit 1402 may output the block select signal BLKSEL_S on the associated block select line BLKSEL_S at the first level to the set of block select switching circuits 1204_S associated with the selected block 1202(S). In response to receipt of the block select signal BLKSEL_S at the first level, the block select switching circuits 1204_S may activate to connect the local CG lines SGDL_S, WL_S(1) to WL_S(M), SGSL S associated with the selected block 1202(S) to the global CG lines SGDL_G, WL_G(1) to WL_G(M), SGSL_G. In addition, as shown in FIG. 14, the global drain select gate bias line SGDL_G is connected to the current sensing circuit 1404. This way, in the event that the global drain select gate bias line SGDL_G receives leakage current during performance of the first leakage current detection process, it may supply the leakage current to the current sensing circuit 1404 so that the current sensing circuit 1404 can sense or monitor for the leakage current.

Additionally, in response to identifying the unselected block 1202(U), the control circuit 1402 may output the block select signal BLKSEL_U on the associated block select line BLKSEL_LU at the second level to the set of block select switching circuits 1204_U associated with the unselected block 1202(U). In response to receipt of the block select signal BLKSEL_U at the second level, the block select switching circuits 1204_U may deactivate to disconnect the local CG lines SGDL_U, WL_U(1) to WL_U(M), SGSL U associated with the unselected block 1202(U) from the global CG lines SGDL_G, WL_G(1) to WL_G(M), SGSL_G.

For some example configurations, and in particular those for performance of the first leakage current detection process, the memory die 104 may further include an N-number of biasing switching circuits and an N-number of logic gates or logic gate circuits. Each logic gate may be associated with and configured to control one of the biasing switching circuits. For some example configurations, each biasing switching circuit is configured as an NMOS transistor, although other configurations may be possible. For configurations where the biasing switching circuits are NMOS transistors, an output of each logic gate may be connected to a gate terminal of an associated NMOS transistor, and control its associated NMOS transistor by turning on and off the associated NMOS transistor.

Each ith switching circuit is associated with an ith block 1202(i) and is connected to the ith local word lines associated with the ith block 1202(i). FIG. 14 shows a first biasing switching circuit 1410(S) associated with the selected block 1202(S) and connected to the local word lines WL_S(1) to WL_S(M) of the selected block 1202(S). In addition, FIG. 14 shows a second biasing switching circuit 1410(U) associated with the unselected block 1202(U) and connected to the local word lines WL_U(1) to WL_U(M) of the unselected block 1202(U).

Each biasing switching circuit may be configured to be activated and deactivated. When a given ith biasing switching circuit 1410(i) is activated, it may be configured to connect the ith local word lines WL_i(1) to WL_i(M) to the low voltage reference SS and bias the ith local word lines WL_i(1) to WL_i(M) to the low reference voltage V_{SS}. As previously described, for some example configurations, the low voltage reference SS is a ground reference, and the low reference voltage V_{SS} is a ground reference voltage. For these example configurations, the biasing switching circuits operate as grounding switching circuits (e.g., grounding transistors) that ground the word lines (i.e., bias the word lines to the ground reference voltage) when activated. Alternatively, when a given ith biasing switching circuit 1410(i) is deactivated, it may be configured to disconnect the ith local word lines WL_i(1) to WL_i(M) to the low voltage reference SS and not bias the ith local word lines WL_i(1) to WL_i(M) to the low reference voltage V_{SS}. Accordingly, when the given ith biasing switching circuit 1410(i) is deactivated, the ith local word lines WL_i(1) to WL_i(M) may be floating with reference to the low voltage reference SS.

FIG. 14 also shows a first logic gate 1412(S) connected to the first biasing switching circuit 1410(S), and a second logic gate 1412(U) connected to the second biasing switching circuit 1410(U). The first logic gate 1412(S) is configured to control whether the first biasing switching circuit 1410(S) is activated or deactivated. Likewise, the second logic gate 1412(U) is configured to control whether the second biasing switching circuit 1410(U) is activated or deactivated. In a particular example configuration, the logic gates are AND gates, although other example configurations are possible.

Each ith logic gate 1412(i) may be configured to receive an associated inverse block select signal BLKSELn_i and a leakage detection signal LEAK_DET from the control circuit 1402. In addition, each ith logic gate circuit 1412(i) may be configured to recognize or identify the first level of the ith inverse block select signal BLKSELn_i as corresponding to a logic “1” value and the second level of the ith inverse block select signal BLKSELn_i as corresponding to a logic “0” values. Also, the control circuit 1402 may be configured to output the leakage detection signal LEAK_DET at a first level indicating that the control circuit 1402 wants to perform the first inter-block leakage current detection process, and at a second level indicating that the control circuit 1402 does not want to perform the first inter-block leakage current detection process. For particular example configurations, each ith logic circuit 1412(i) may identify or recognize the first level of the leakage detection signal LEAK_DET as corresponding to a logic “1” value, and the second level of the leakage detection signal LEAK_DET as corresponding to a logic “0” value.

When the control circuit 1402 wants to perform the first leakage current detection process, it may output the leakage detection signal LEAK SET to the logic gates at the first level indicating that it wants to perform the first leakage current detection process. The first logic gate 1412(S) associated with the selected block 1202(S) may receive the inverse block select signal BLKSELn_S at the second level corresponding to the logic “0” value and the leakage detection signal LEAK_DET at the first level corresponding to the logic “1” value, and as an AND gate, generate its output at a level corresponding to the logic “0” value, which in turn may deactivate the first biasing switching circuit 1410(S). Accordingly, for the selected block 1202(S), when the control circuit 1402 wants to perform the first leakage current detection process, the control circuit 1402 outputs the inverse block select signal BLKSELn_S at the second level and the leakage detection signal LEAK_DET at the first level, which causes the biasing switching circuit 1410(S) to deactivate, and in turn, the local word lines WL_S(1) to WL_S(M) associated with the selected block 1202(S) to be disconnected from the low voltage reference SS.

Concurrently, the second logic gate 1412(U) associated with the unselected block 1202(U) may receive the inverse block select signal BLKSELn_U at the first level corresponding to the logic “1” value and the leakage detection signal LEAK_DET at the first level corresponding to the logic “1” value, and as an AND gate, generate its output at a level corresponding to the logic “1” value, which in turn may activate the second biasing switching circuit 1410(U). Accordingly, for the unselected block 1202(U), when the control circuit 1402 wants to perform the first leakage current detection process, the control circuit 1402 outputs the inverse block select signal BLKSELn_U at the first level and the leakage detection signal LEAK_DET at the first level, which causes the biasing switching circuit 1410(U) to activate, and in turn, the local word lines WL_U(1) to WL_U(M) associated with the unselected block 1202(U) to be connected to the low voltage reference SS and be biased to the low reference voltage V_{SS}. In this context, the low reference voltage V_{SS} is the second leakage voltage to which the second biasing switching circuit 1410(U) biases the local word lines WL_U(1) to WL_U(M) associated with the unselected block 1202(U) for performance of the first leakage current detection process.

With the local word lines WL_U(1) to WL_U(M) associated with the unselected block 1202(U) biased to the low reference voltage V_{SS}, the control circuit 1402 may control the voltage supply circuit 1408 to supply the drain select gate bias voltage V_{SGD} at the first leakage voltage level. The first leakage detection level or first leakage test level may be a sufficiently high voltage level such that the difference between the first leakage detection level and the level of the low reference voltage V_{SS} is great enough to generate leakage current in the event that a short exists between the local drain select gate bias line SGDL_S associated with the selected block 1202(S) and at least one of the word lines WL_U(1) to WL_U(M) associated with the unselected block 1202(U). For some example configurations, the first leakage detection level may be a program voltage level, i.e., a voltage level applied to a selected word line for programming. An example first leakage detection level may be around 20 V or higher.

In addition, with the set of block select switching circuits 1204_S being activated and connecting the local CG lines SGDL_S, WL_S(1) to WL_S(M), SGSL S associated with the selected block 1202(S) to the global CG lines SGDL_G, WL_G(1) to WL_G(M), SGSL_G, the voltage supply circuit 1408 may supply the drain select gate bias voltage V_{SGD} at the first leakage detection level to the SGD block select switching circuit 1204_S(SGD). Being activated, the SGD block select switching circuit 1204_S(SGD) may receive the drain select gate bias voltage V_{SGD} at the first leakage detection level and in response, bias the local drain select gate bias line SGDL_S with the drain select gate bias voltage V_{SGD} at the first leakage detection level.

The control circuit 1402 may maintain the block select signals BLKSEL, the inverse block select signals BLKSELn, the leakage detection signal LEAK_DET, and the drain select gate bias voltage V_{SGD} at their respective voltage levels for a predetermined time period so that the local drain select gate bias line SGDL_S associated with the selected block 1202(S) is biased with the first leakage detection voltage and the local word lines WL_U(1) to WL_U(M) associated with the unselected block 1202(U) are biased to the low reference voltage V_{SS} for the predetermined time period.

During this predetermined time period, in the event that there is a short between the local drain select gate bias line SGDL_S associated with the selected block 1202(S) and one or more of the local word lines WL_U(1) to WL_U(M) associated with the unselected block 1202(U), leakage current due to the short may flow through the local drain select gate bias line SGDL_S, through the activated SGD block select switching circuit 1204_S(SGD), through the global drain select gate bias line SGDL_G, and into the current sensing circuit 1404. Additional details of the current sensing circuit 1404 are described in further detail below.

Before turning to the second example current leakage detection process, of note is that without the biasing switching circuits 1410 and their associated control gates 1412, the local word lines WL_U(1) to WL_U(M) associated with the unselected block 1202(U) would be kept floating during performance of the first leakage current detection process. If such were the case, any shorts between the drain select gate bias line SGDL_S associated with the selected block 1202(S) and the local word lines WL_U(1) to WL_U(M) associated with the unselected block 1202(U) would not be detected since leakage current would not be generated. Accordingly, by adding the biasing switching circuits 1410 and their associated control gates 1412, local word lines WL_U(1) to WL_U(M) associated with the unselected blocks 1202(U) can be biased to the low reference voltage V_{SS} so that leakage current can be generated during performance of the first leakage current detection process in the event that a short is present.

Additionally, although the first example leakage current detection process is described as being performed for one unselected block 1202(U), for other example configurations, the control circuit 1402 is configured to identify multiple unselected blocks 1202(U) for performance of the first leakage current detection process. For example, the control circuit 1402 may be configured to identify all of the N-number of blocks 1202(1) to 1202(N) besides the selected block 1202(S) as unselected blocks 1202(U). For configurations where multiple blocks are unselected, the operations performed for the multiple unselected blocks are the same as those performed for the single unselected block 1202(U) shown and described with reference to FIG. 14.

With particular reference to FIG. 15, for performance of the second example leakage current detection process, the control circuit 1402 may be configure to select two of the blocks 1202(1) to 1202(N). For some example configurations, the two blocks that the control circuit 1402 selects have physically adjacent transfer regions. In addition, the voltage supply circuit 1408 may supply the drain select gate bias voltage V_{SGD} at the first leakage detection voltage level to local drain select gate bias lines associated with the two selected blocks, and concurrently supply the word line voltages V_{WL1} to V_{WLM} at the second leakage detection level or leakage test level to local word lines associated with the two selected blocks. The control circuit 1402 may control the second leakage current detection process so that the local drain select gate bias lines associated with the selected blocks are biased to the first leakage detection voltage and the local word lines associated with the selected block are biased to the second leakage detection voltage for a predetermined time period. During this time period, the current sensing circuit 1404, which is connected to the global drain select gate bias line SGDL_G, may sense and/or or monitor for leakage current flowing in the global drain select gate bias line SGDL_G.

In further detail, the control circuit 1402 may be configured to identify two of the blocks 1202(1) to 1202(N) as selected blocks. As used herein, the label “S1” is used to denote “first selected” and the label “S2” is used to denote “second selected.” Accordingly, as shown in FIG. 15, the label “1202(S1)” denotes a first selected block, and the label “1202(S2)” denotes a second selected block for the second example leakage current detection process.

In response to identifying the first selected block 1202(S1), the control circuit 1402 may output the block select signal BLKSEL_S1 on the associated block select line BLKSEL_LS1 at the first level to the set of block select switching circuits 1204_S1 associated with the first selected block 1202(S1). In response to receipt of the block select signal BLKSEL_S1 at the first level, the block select switching circuits 1204_S1 may activate to connect the local CG lines SGDL_S1, WL_S1(1) to WL_S1(M), SGSL_S1 associated with the first selected block 1202(S1) to the global CG lines SGDL_G, WL_G(1) to WL_G(M), SGSL_G.

Similarly, in response to identifying the second selected block 1202(S2), the control circuit 1402 may output the block select signal BLKSEL_S2 on the associated block select line BLKSEL_LS2 at the first level to the set of block select switching circuits 1204_S2 associated with the second selected block 1202(S2). In response to receipt of the block select signal BLKSEL_S2 at the first level, the block select switching circuits 1204_S2 may activate to connect the local CG lines SGDL_S2, WL_S2(1) to WL_S2(M), SGSL_S2 associated with the second selected block 1202(S2) to the global CG lines SGDL_G, WL_G(1) to WL_G(M), SGSL_G.

In addition, as shown in FIG. 15, the global drain select gate bias line SGDL_G is connected to the current sensing circuit 1404. This way, in the event that the global drain select gate bias line SGDL_G receives leakage current during performance of the second leakage current detection process, it may supply the leakage current to the current sensing circuit 1404 so that the current sensing circuit 1404 can sense or monitor for the leakage current.

With the set of block select switching circuits 1204_S1 being activated and connecting the local CG lines SGDL_S1, WL_S1(1) to WL_S1(M), SGSL_S1 associated with the first selected block 1202(S1) with the global CG lines SGDL_G, WL_G(1) to WL_G(M), SGSL_G, and concurrently with the set of block select switching circuits 1204_S2 being activated and connecting the local CG lines SGDL_S2, WL_S2(1) to WL_S2(M), SGSL_S2 associated with the second selected block 1202(S2) with the global CG lines SGDL_G, WL_G(1) to WL_G(M), SGSL_G, the voltage supply circuit 1408 may supply the drain select gate bias voltage V_{SGD} at the first leakage detection level to the SGD block select switching circuit 1204_S1(SGD) and to the SGD block select switching circuit 1204_S2(SGD), and concurrently supply the word lines voltages V_{WL1} to V_{WLM} at the second leakage detection level to the WL block select switching circuits 1204_S1(WL1) to 1204_S1(WLM) and to the WL block select switching circuits 1204_S2(WL1) to 1204_S2(WLM). Being activated, the SGD block select switching circuits 1204_S1(SGD) and 1204_S2(SGD) may receive the drain select gate bias voltage V_{SGD} at the first leakage detection level and in response, bias their respective local drain select gate bias line SGDL_S1, SGDL_D2 with the drain select gate bias voltage V_{SGD} at the first leakage detection level. Concurrently, the WL block select switching circuits 1204_S1(WL1) to 1204_S1(WLM) and 1204_S2(WL1) to 1204_S2(WLM) may receive the word line voltages V_{WL1} to V_{WLM} at the second leakage detection level and in response, bias their respective local word lines WL_S1(1) to WL_S2(M) and WL_S2(1) to WL_S2(M).

In the second leakage current detection process, the first leakage detection voltage and the second leakage detection voltage may set to appropriate levels so that the difference between the first leakage detection level and the second leakage detection level is great enough to generate leakage current in the event that a short exists between the local drain select gate bias line SGDL_S1 associated with the first selected block 1202(S1) and at least one of the local word lines WL_S2(1) to WL_S2(M) associated with the second selected block 1202(S2), and/or between the local drain select gate bias line SGDL_S2 associated with the second selected block 1202(S2) and at least one of the local word lines WL_12(1) to WL_S1(M) associated with the first selected block 1202(S1). For some example configurations, the first leakage detection level is higher in magnitude than the second leakage detection level. In addition or alternatively, the first leakage detection level may be a program voltage level, i.e., a voltage level applied to a selected word line for programming. An example first leakage detection level may be around 20 V or higher. Additionally, for some example configurations, the second leakage detection level may be the level of the low reference voltage V_{SS}, or another relatively low voltage level compared to the level of the first leakage detection voltage, such as 2 V for example.

The control circuit 1402 may maintain the block select signals BLKSEL_S1, BLKSEL_S2, the drain select gate bias voltage V_{SGD}, and the word lines voltages V_{WL1} to V_{WLM} at their respective voltage levels for a predetermined time period so that the local drain select gate bias lines SGDL_S1, SGDL_S2 are biased with the first leakage detection voltage and the local word lines WL_S1(1) to WL_S1(M) and WL_S2(1) to WL_S2(M) are biased to the second leakage detection voltage for the predetermined time period.

During this predetermined time period, in the event that there is a short between the local drain select gate bias line SGDL_S1 associated with the first selected block 1202(S1) and at least one of the local word lines WL_S2(1) to WL_S2(M) associated with the second selected block 1202(S2), and/or between the local drain select gate bias line SGDL_S2 associated with the second selected block 1202(S2) and at least one of the local word lines WL_12(1) to WL_S1(M) associated with the first selected block 1202(S1), leakage current due to the short(s) may flow through one or both of the local drain select gate bias lines SGDL_S1, SGDL_S2, through one or both of the activated SGD block select switching circuits 1204_S1(SGD), 1204_S2(SGD), through the global drain select gate bias line SGDL_G, and into the current sensing circuit 1404.

Referring to both the first and second leakage current detection processes, the current sensing circuit 1404, also referred to as a current monitoring circuit, may be configured to sense for leakage current during the predetermined time period. Sensing for leakage current may also include sensing an amount of the leakage current. In some example configurations, the current sensing circuit 1404 may be configured to generate an output signal, such as an output voltage or an output current indicative of the sensing and/or a sensed amount of the leakage current. The current sensing circuit 1404 may be configured to output the output signal to the comparison circuit 1406.

In response to the output signal, the comparison circuit 1406 may be configured to compare the sensed amount of leakage current with a threshold current level. The comparison circuit 1406 may further be configured to generate a comparison result signal RSLT that indicates a result of the comparison. In particular, the comparison circuit 1406 may be configured to generate the comparison result signal RSLT to indicate whether the leakage current sensed during the predetermined time period exceeded the threshold current level. The comparison circuit 1406 may be configured to output the comparison result signal RSLT to the control circuit 1402.

In response to receipt of the comparison result signal RSLT, the control circuit 1402 may identify a usability for the select block(s). In particular, if the comparison result signal RSLT indicates that leakage current did not exceed the threshold current level, then the control circuit 1402 may identify the selected block(s) as usable. Alternatively, if the comparison result signal RSLT indicates that the leakage current exceeded the threshold current level, then the control circuit 1402 may identify the selected block(s) as unusable. A usable usability status for a given block indicates that data can be stored in the given block. An unusable usability status for a given block indicates that data is not to be stored in the given block. In some example configurations, the control circuit 1402 may notify the controller 102 (FIG. 2A) of its determination of whether the selected block(s) is/are usable or unusable. In other example configurations, the control circuit 1402 may notify the controller 102 only in the event that it determines that the selected block(s) is/are unusable. In still other example configurations, the control circuit 1402 may notify the controller 102 of the comparison result RSLT without making a usability status determination, and the controller 102 can determine whether or not the selected block(s) is/are usable or unusable. Various configurations for handling the comparison result signal RSLT for making a usability determination may be possible.

Additionally, for some example configurations, the leakage current detection circuitry 1400 may be configured to perform the first or second leakage current detection tests in response to receipt of a write request, such as a host write request received from a host system. For example, the controller 102, in response to receipt of a host write request to write data into the memory 142 (FIG. 2B), may instruct a memory die 104 to program the data into a particular one of the N-number of blocks 1202(1) to 1202(N). In response, the control circuit 1402 may determine to perform either the first or second leakage current detection processes. In the event that the leakage current detection process identified the selected block(s) as unusable, the control circuit 1402 may notify the controller 102 to select a new block or set of blocks in which to program the data. Alternatively, the control circuit 1402 select the new block(s), have the data programmed into the newly selected blocks, and then notify the controller 102.

In other example configurations, the leakage current detection circuitry 1400 may be configured to perform the first or second leakage current detection processes as a background memory management process, as opposed to a process that is performed expressly in response to receipt of a particular host request. That is, the memory system 100 may be configured to perform background operations as part of its memory management that is not specific to a received host request. For example, a background process may monitor the health of a block, such as by monitoring the number of program-erase cycles of that block or the number of times the block was accessed for a read operation, as non-limiting examples. In response to the monitoring, the control circuit 1402 may determine to perform either the first leakage current detection process or the second current leakage detection process for one or more blocks.

It is intended that the foregoing detailed description be understood as an illustration of selected forms that the invention can take and not as a definition of the invention. It is only the following claims, including all equivalents, that are intended to define the scope of the claimed invention. Finally, it should be noted that any aspect of any of the preferred embodiments described herein can be used alone or in combination with one another.

We claim:

1. A circuit comprising:
a memory array comprising a plurality of memory cells arranged into a plurality of blocks;
a control circuit configured to identify a first block of the plurality of blocks and a second block of the plurality of blocks;
a first switching circuit configured to bias a select gate bias line of the first block with a first leakage detection voltage; and
a second switching circuit configured to bias one or more word lines of the second block with a second leakage detection voltage; and
a current sensing circuit configured to sense for leakage current between the select gate bias line of the first block and the one or more word lines of the second block during concurrent bias of the select gate bias line of the first block with the first leakage detection voltage and the one or more word lines of the second block with the second leakage detection voltage.

2. The circuit of claim 1, further comprising a comparison circuit configured to:
compare a level of the leakage current with a threshold current level; and
output a comparison result signal indicative of the comparison to the control circuit.

3. The circuit of claim 1, wherein the current sensing circuit is configured to sense for leakage current caused by a short between the select gate bias line of the first block and the one or more word lines of the second block.

4. The circuit of claim 1, wherein the control circuit is further configured to:
determine to perform an inter-block leakage current detection process in response to receipt of a host write request; and
identify the first block and the second block in response to the determination.

5. The circuit of claim 1, wherein the word line voltage comprises a ground reference voltage, and
wherein the switching circuit is configured to connect the one or more word lines to a ground reference to bias the one or more word lines to the ground reference voltage.

6. The circuit of claim 1, wherein the control circuit is further configured to:
identify the first block as a selected block; and
identify a plurality of blocks in a plane besides the first block as unselected blocks, the selected block comprising one of the unselected blocks.

7. The circuit of claim 6, wherein the plurality of blocks in the plane besides the first block comprises all of the blocks in the plane besides the first block.

8. The circuit of claim 1, further comprising a logic gate circuit configured to control the switching circuit,
wherein the logic gate circuit is configured to activate the switching circuit to bias the one or more word lines to the second leakage detection voltage in response to receipt of an inverse block select signal associated with the second block and a leakage detection signal indicating that the control circuit wants to perform an inter-block leakage current detection process.

9. The circuit of claim 8, wherein the switching circuit comprises a first switching circuit and the logic gate comprises a first logic gate, wherein the circuit further comprises:
a second switching circuit configured to bias one or more word lines of the first block to the second leakage detection voltage; and
a second logic gate configured to control the second switching circuit,
wherein the second logic gate circuit is configured to deactivate the second switching circuit in response to receipt of an inverse block select signal associated with the first block and the leakage detection signal indicating that the control circuit wants to perform the inter-block leakage current detection process.

10. The circuit of claim 1, further comprising:
a third switching circuit configured to bias a select gate bias line of the second block with the first leakage detection voltage; and
a fourth switching circuit configured to bias one or more word lines of the first block with the second leakage voltage, and
wherein the current sensing circuit is further configured to sense for leakage current further between the select gate bias line of the second block and the one or more word lines of the first block during concurrent bias of: the select gate bias line of the first block and the select gate bias line of the second block with the first leakage detection voltage, and of the one or more word lines of the first block and the one or more word lines of the second block with the second leakage detection voltage.

11. The circuit of claim 10, wherein the first block and the second block are associated with physically adjacent transfer regions.

12. The circuit of claim 1, wherein the select gate bias line comprises a drain select gate bias line.

13. A circuit comprising:
a control circuit configured to:
select two blocks of a plurality of blocks as a first selected block and a second selected block for performance of an inter-block leakage current detection process; and
a voltage supply circuit configured to:
supply a select gate bias voltage at a first leakage detection level to a first local select gate bias line of the first selected block and to a second local select gate bias line of the second selected block; and
supply a plurality of word line voltages at a second leakage detection level to one or more first local word lines associated with the first selected block and to one or more second local word lines associated with the second selected block; and
a leakage current detection circuit configured to sense for leakage current between at least one of the first local select gate bias line and the one or more second local word lines, or the second local select gate bias line and the one or more first local word lines.

14. The circuit of claim 13, wherein the first selected block and the second selected block are associated with physically adjacent transfer regions.

15. The circuit of claim 13, wherein the control circuit is further configured to:
in response to selection of the first selected block and the second selected block:
send a first block select signal to a first set of pass transistors to select the first selected block; and
send a second block select signal to a second set of pass transistors to select the second selected block.

16. The circuit of claim 13, wherein the first select gate bias line comprises a first drain select gate bias line and the second select gate bias line comprises a second drain select gate bias line.

17. A system comprising:
a memory die comprising nonvolatile memory cells organized into a plurality of blocks;
a control circuit configured to:
output a block select signal to connect local control gate lines of a selected block of the plurality of blocks with global control gate lines, wherein one of the local control gate lines comprises a local drain select gate bias line; and
output a leakage detection signal to connect local word lines of a second block to a ground reference;
a voltage supply circuit configured to supply a drain select gate bias voltage at a leakage test level to the local drain select gate bias line of the first block in response to the local control gate lines of the first block connected to the global control gate lines and the local word lines of the second block connected to the ground reference; and
a leakage current monitor circuit configured to:
connect to the local drain select bias line of the first block in response to the output of the block select signal; and
monitor for leakage current between the local drain select gate bias line of the first block and the local word lines of the second block during supply of the of the drain select gate bias voltage at the leakage test level and connection of the local word lines of the second block to the ground reference.

18. The system of claim 17, further comprising:
a grounding transistor configured to connect the local word lines of the second block to the ground reference.

19. The system of claim 18, further comprising:
a logic gate circuit configured to control the grounding transistor,
wherein the logic gate circuit is configured to turn on the grounding transistor to bias the local word lines of the second block to a ground reference voltage associated with the ground reference in response to receipt of the leakage detection signal.

20. The system of claim 17, wherein the plurality of blocks are configured in a same plane.
